(19) United States
(12) Patent Application Publication
(10) Pub. No.: US 2009/0008146 A1
(43) Pub. Date: Jan. 8, 2009

(54) Optimizing in-building wireless signal propagation while ensuring data network security

(76) Inventor: Michael William Oleske, Lancaster, PA (US)

Correspondence Address: John M. Olivo;Armstrong World Industries, Inc., 2500 Columbia Avenue, P. O. Box 3001, Lancaster, PA, 17604-3001, US

(21) Appl. No.: 12/077,132

(22) Filed: Mar. 17, 2008

Related U.S. Application Data
(60) Provisional application No. 60/918,618, filed on Mar. 16, 2007.

(51) Int. Cl. H05K 9/00

(52) U.S. Cl. 174/350

(57) ABSTRACT

A shield capable of attenuating wireless signals on demand has been created using a conductive member, such as a metal mesh or perforated metal sheet, which is either coupled to ground or subjected to an electron flow. A metal enshrouded signal isolation chamber was built and a wireless router was placed inside it. With the top of the chamber open, a plurality of conductive assemblies were evaluated by placing each conductive assembly on top of the open chamber, one at a time, and measuring the resulting signal attenuation.

### CROSS REFERENCE TO RELATED APPLICATION

This application claims the benefit under 35 U.S.C. §119(e) of U.S. provisional application Ser. No. 60/918,618 filed Mar. 16, 2007.

### FIELD OF THE INVENTION

The present invention is directed to wireless technology, and more specifically to a shield capable of enhancing the security of in-building wireless communications without compromising the freedom and benefits associated with wireless technology.

### BACKGROUND OF THE INVENTION

Local Area Networks (LANs) are connection systems that enable devices such as computers to share access to data, programs, peripheral devices and even connections to the Internet. LANs are used by many businesses, schools, and even in homes. Originally, LANs were setup by hardwiring computers directly to each other or through a central server. Wired systems require each user to be physically connected, i.e. tethered, to the network. If a network connection or outlet does not already exist in a particular location, then one must be added. This often requires cutting into walls and ceilings in order to bring the network cabling to the desired location. This type of renovation can be very time consuming and expensive, especially if the buildings are older or of historic significance.

The application of wireless LANs (WLANs) has grown dramatically in the last several years. WLANs are LANs that do not make use of hardwiring for interconnectivity. Eliminating the need for wiring provides a great deal of freedom to the user, and can reduce installation costs for the system owner. For example, if a business has a WLAN, they can easily add employees to the network, or allow them to change locations without the expense of rewiring and/or remodeling. A WLAN allows employees with wireless laptops to access the web and retrieve and share files anywhere a signal is available. Also, employees can move from location to location while remaining connected, thus increasing their productivity.

In any WLAN, however, there is a need to balance signal propagation, i.e. having a strong signal where it is needed, with network security as available WLAN signals can be an open invitation to intruders who want to sabotage your network or steal your data. For example, unauthorized people accessing non-secure wireless connections and entering a WLAN could implant viruses into the network resulting in the loss of information or making the network run more slowly. More significantly, homeowners could see their identities stolen, university researchers could see their findings or ideas stolen and businesses could lose sensitive market data or other secret information. Even national security could be at risk if the WLANs of government agencies such as the FBI, State Department, or Department of Homeland Security were compromised. These threats to data security can affect everyone, and, thus, there is a need for a wireless signal shielding system capable of enhancing the security of WLANs without compromising the freedom and benefits associated with wireless technology.

### SUMMARY OF THE INVENTION

The present invention relates to an enhanced shield for attenuating wireless signals. The shield includes at least one electrically conductive member. In a first example embodiment, the conductive member is selectively coupled to either a ground member or to an electron flow. In an alternative example embodiment, two continuous conductive members are selectively coupled to one another electrically. In the instance of more than one conductive member, the conductive members are preferably overlaid. In either example embodiment, the conductive member, or members, can be selectively coupled to either allow or block a signal from passing. The conductive members are preferably placed proximate to a surface of a building construction element such as a wall, floor, ceiling, door, or furniture assembly.

A major advantage of the shield of the invention is that it allows building occupants to selectively make their spaces either closed or open to wireless signals depending on the need.

### BRIEF DESCRIPTION OF THE DRAWINGS

FIG. 1 is a perspective view of a test chamber.

FIG. 2 is a top view of the test chamber shown in FIG. 1.

FIG. 3 is a top plan view of a section of a first example embodiment of two electrically conductive members which are aligned with one another.

FIG. 4 is a top plan view of a section of a first example embodiment of two electrically conductive members which are offset from one another.

FIG. 5 is a top plan view of a section of a second example embodiment of two electrically conductive members which are aligned with one another.

FIG. 6 is a top plan view of a section of a second example embodiment of two electrically conductive members which are offset from one another.

FIG. 7 is a top plan view of a section of a third example embodiment of two electrically conductive members which are aligned with one another.

FIG. 8 is a top plan view of a section of a third example embodiment of two electrically conductive members which are offset from one another.

FIG. 9 is a plot showing the attenuation performance for all seventy-one test assembly conditions.

FIG. 10 is a plot showing the attenuation performance associated with thin aluminum based assemblies when tied to ground.

FIG. 11 is a plot showing the attenuation performance associated with thin aluminum based assemblies when charged to 9 volts.

FIG. 12 is a plot showing the attenuation performance of wide expanded aluminum assemblies when tied to ground.

FIG. 13 is a plot showing the attenuation performance of narrow expanded aluminum assemblies when tied to ground.

FIG. 14 is a plot showing the attenuation performance of perforated steel assemblies when tied to ground.

FIG. 15 is a plot showing the attenuation performance of grounded open aluminum mini-blinds, closed aluminum mini-blinds and closed vinyl mini-blinds

### DESCRIPTION OF THE INVENTION

In any WLAN, there are two key components; the access point, which is connected to a wired LAN or the Internet, through devices such as a cable modem or DSL line, and the receiving device, such as a computer, printer, scanner, etc. The receiving device and the access point each contain a radio transmitter/receiver, commonly referred to in industry as a transceiver, as well as an antenna, which allows both the receiving device and the access point to transmit and receive signals.

WLAN components communicate with one another using the industrial, scientific, and medical frequency bands (ISM bands). These are the radio frequency bands which the Federal Communications Commission (FCC) has authorized for these types of devices. The ISM bands include: 902 MHz, 2.4 GHz, and 5 GHz. WLAN devices that are compliant with the 802.11b and 802.11g standards on wireless communication use the 2.4 GHz frequency band, while devices compliant with the 802.11a standard on wireless communication use the 5 GHz band. It should be noted, the standard on wireless communication in 1997 was developed by the Institute of Electrical and Electronic Engineers (IEEE), which is a United States based organization that develops standards for the electronics industry.

Many devices such as microwave ovens and cordless phones also use the 2.4 GHz band. As is commonly known, the higher the frequency, the shorter the wavelength and the more focused, i.e. narrower, the signal beacon. Thus, while the use of the 5 GHz frequency band can reduce the potential for interference, its use will require more access points to ensure that the transmitting and receiving devices can “see” each other.

The term attenuation refers to the reduction in strength of a signal as it travels from its source to a receiver. WLAN signals obey the inverse square law with respect to distance and thus signal strengths attenuate with the square of the distance from the source. See Benksy, Alan, Short-Range Wireless Communication, Eagle Rock, Va.: LLH Technology Publishing, 2000. A typical WLAN will have an effective range of 150 to 900 feet, depending on the output power, data rate, and building construction. See Geier, Jim. Wireless LANs. Ed. Matt Purcell. 2^{nd} Ed. Indianapolis: Sams Publishing, 2002. Regardless of the type of signal (audio, electromagnetic, etc.), attenuation is measured in decibels using the formula:

A_{P}=10 log₁₀ (P_{source}/P_{receiver})

Where P_{source} is the power at the source (in Watts or miliWatts), P_{receiver} is the power at the receiver (again in W or mW), and A_{P} is the power attenuation in decibels (dB). See Egan, M. David. Architectural Acoustics. New York: McGraw Hill, Inc., 1988. A drop in signal strength of 3 dB therefore means that the signal is only half as strong at the receiver as compared to its strength at the source

As previously mentioned, in any WLAN there is a need to balance signal propagation with security. An enhanced shielding system that enables good wireless signal propagation while simultaneously ensuring data network security is described in detail below. To test the capability of several shield assemblies, an in-building WLAN was set up and a signal strength for each shield assembly was measured as a function of receiver location, in this case a wireless laptop, and the distance of the receiver from a fixed access point. This testing was done using an 802.11 compatible laptop computer and the standard signal strength analysis software that comes with Windows XP (Service Pack 2 operating system). The receiver location and distance were the control variables and the signal strength was the dependent variable.

A series of shields were fabricated using both ferrous and non-ferrous metals, such as perforated and non-perforated steel, aluminum foil, and wire mesh, as well as non-conductive material, such as gypsum board or plywood. The shield assemblies were then placed between the access point and the receiving device, and the impact on signal strength was recorded. Signal strength was evaluated with the conductive shield assemblies at:
a. ground
b. floating (electrically isolated)
c. carrying a small voltage (e.g. 9 volts)
d. subjected to a magnetic field.
   Shield construction and charge were also, therefore, control variables, while signal strength remained the dependent variable.

### Attenuation Testing

Prior to conducting the attenuation testing, a location that was free from any extraneous WLAN signals was sought and found. Making sure that the WLAN test signal was the only signal detected by the monitoring program was important to ensure the integrity of the data as a network other than the one being selectively shielded, if detectable, would have confounded the results. This is because as the WLAN test signal was made weaker by shielding, the internal signal detection software in the receiving device would have automatically found and switched to any stronger WLAN signals that were available. Thus, all trials run during the course of the testing were conducted at a below grade location.

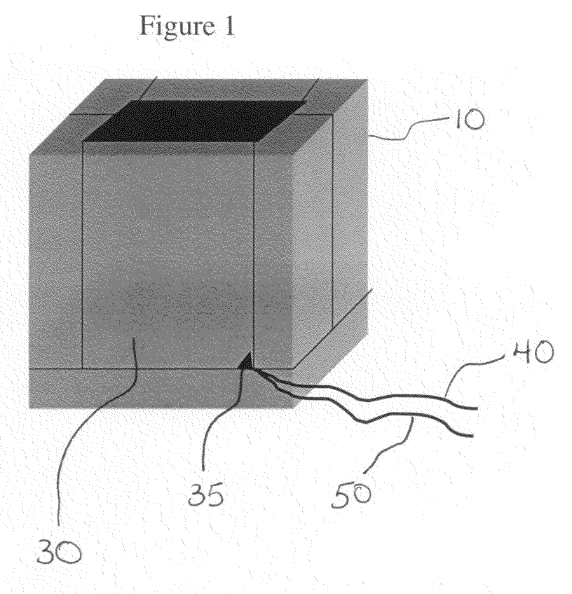

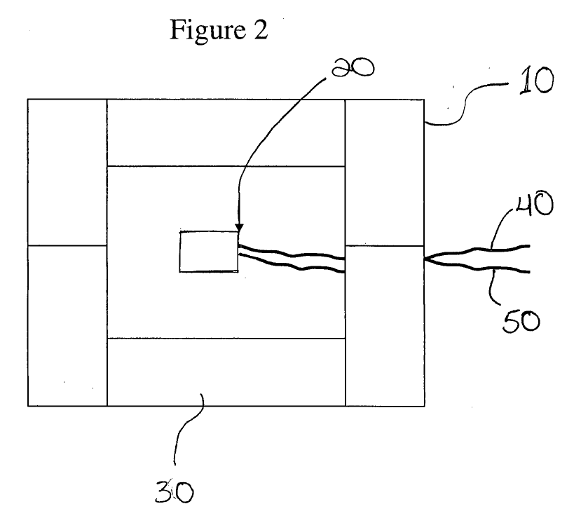

The next step was to confirm that the closed test chamber 10, shown in FIGS. 1 and 2, was capable of completely attenuating the WLAN signal being generated by the wireless transceiver 20. The ability of the test chamber 10, especially its walls, to completely and reliably attenuate the WLAN signal is critical. Here, the closed test chamber 10 achieved full WLAN signal attenuation at 10 meters distance. Since the walls of the chamber 10 were able to block any WLAN signals that struck them, this guaranteed that any test assembly placed on top of the open test chamber 10 would be responsible for the signal strength detected at the receiving unit.

The following is a list of materials utilized in the attenuation testing. Below the list of materials is a listing of the method steps for constructing a wireless signal shielding chamber; followed by the installation and set up steps of a WLAN. Materials:
1. Desktop computer with Windows XP, Service Pack 2 operating system
2. Wireless router kit 20 (FIG. 2) (including connection cables and software)
3. An 802.11 compatible wireless laptop computer (not shown) with Windows XP, Service Pack 2 operating system
4. One role of aluminum foil
5. Non-perforated steel 25 cm×25 cm×0.07 cm
6. Two pieces of perforated steel with 0.32 cm diameter holes and even hole spacing (0.48 cm on center)—size 25 cm×25 cm×0.07 cm
7. Two pieces of wide expanded aluminum—size 25 cm×25 cm×0.07 cm
8. Two pieces of narrow expanded aluminum—size 25 cm×25 cm×0.07 cm
9. One piece of fine aluminum mesh—size 25 cm×25 cm×0.07 cm
10. Aluminum mini-blinds
11. Vinyl mini-blinds
12. Gypsum board 25 cm×25 cm×1.5 cm
13. Plywood 25 cm×25 cm×2 cm
14. Low Density Fiberboard (such as ceiling tile) 1.2-1.8 cm thick—size 25 cm×25 cm
15. Fiberglass board (such as ceiling tile or duct liner) 5 cm thick—size 25 cm×25 cm
16. 9 volt battery
17. Electrical leads for 9 volt
18. Copper wire connected to earth ground
19. Magnets
20. Six Concrete Masonry Units (CMU) nominally 9 cm×20 cm×40 cm, with a density ≧2.1 g/cm³
21. Two Concrete Masonry Units (CMU) nominally 40 cm×40 cm×7 cm, with a density ≧2.1 g/cm³
22. Four pieces of non-perforated steel 18.5 cm×39.5 cm×0.1 cm
23. one piece of non-perforated steel 18.5 cm×18.5 cm×0.1 cm
24. Metric Tape Measure
25. Hammer
26. Chisel
27. Safety glasses
28. Gloss Latex Paint
29. Paintbrush
30. Latex Caulk
31. Caulking Gun
32. Leveling Compound (Liquid Nails)
33. Spatula or Trowel

### Methods:

### I. Constructing Wireless Signal Shielding Chamber 10 (FIGS. 1 and 2)

1. Provided one of the 9 cm×20 cm×40 cm CMU's 30 (FIG. 1) and used a metric tape measure mark a line 1 cm from the corner on the 9×20 side.
2. Used a metric tape measure mark a second line 1 cm from the edge on the same CMU 30 on the adjacent 9×40 side (forming a 1 cm×1 cm right triangle).
3. Put on safety glasses.
4. Used a hammer and chisel to chip off the marked corner section 35 from the CMU 30 marked in step 2 to form a wire way for the router's power cable 40 and signal cable 50 (FIGS. 1 and 2)).
5. Painted all surfaces of the CMU's with 2 coats of the gloss latex paint and allowed the painted CMU's to dry overnight between coats.
6. Selected a space in close proximity to the desktop computer that is free of obstructions to build the wireless signal shielding chamber.
7. In that space, placed one of the 40 cm×40 cm×7 cm CMU's (forming a 40 cm×40 cm square base for the wireless signal shielding chamber).
8. On top of this base, along one edge, placed two of the 9 cm×20 cm×40 cm CMU's, with their 9 cm×20 cm sides against the base, and their 9 cm×40 cm sides touching each other.
9. Placed the chiseled CMU 30 from step 4 on top of the base (with the chiseled 9 cm×20 cm edge against the base).
10. Aligned the CMU 30 from step 9 perpendicular to one of the upright CMU's already in place.
11. Placed two more of the 9 cm×20 cm×40 cm CMU's, with the 9 cm×20 cm side against the base, on the side opposite the two CMU's positioned in step 8, and perpendicular to the chiseled CMU positioned in step 10.
12. Placed the last painted CMU along the edge of the base to fill in the open spot to form and open top chamber 10 as shown in FIG. 2.
13. Placed the latex caulk in the caulking gun and prepare it for use.
14. Removed one of the upright CMU's from a corner on the base, place caulk along the side that will touch the base and re-place it on the base.
15. Working clockwise, removed an adjacent CMU and again place a layer of caulk on the side that will touch the base and also a layer of caulk on the side that will touch the CMU already caulked in place (be sure that the caulked, upright CMU's are even in height).
16. Repeated step 15 for the chiseled CMU.
17. Placed the 18.5 cm×18.5 cm×0.1 cm piece of non-perforated steel in the bottom of the test chamber.
18. Fed the router power and signal cables (40 and 50 respectively, FIGS. 1 and 2) through the chiseled out wire way and fill any open space with caulk.
19. Attached the cables 40 and 50 to the router 20.
20. Placed the router 20 into the wireless signal shielding chamber 10 on top of the steel plate.
21. Repeated step 15 for the remaining CMU's.
22. Caulked all joints between CMU's.
23. Allowed caulk to cure at least 24 hours before proceeding.
24. Inserted the four pieces of non-perforated steel 18.5 cm×39.5 cm×0.1 so as to line the four inside walls of the test chamber 10.
25. Along the top 9 cm×20 cm edges of the upright CMU's, spread leveling compound with a spatula or trowel to make a smooth surface.
26. Allowed leveling compound to sit for at least 24 hours.
27. Wrapped the outside wall and exposed top surfaces of the test chamber 10 with two layers of aluminum foil.

### Installation and Set Up of Wireless LAN

28. Following the instructions provided by the wireless router supplier, installed the wireless router software and attached the wireless router CAT 5 signal cable to the desktop computer.

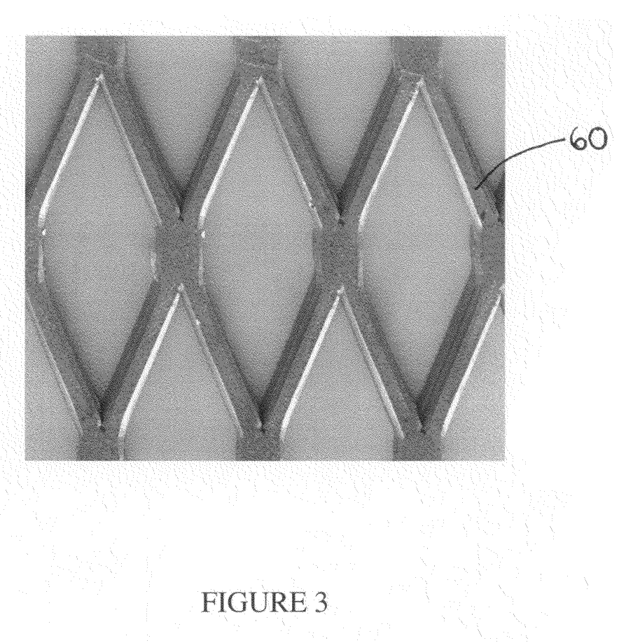

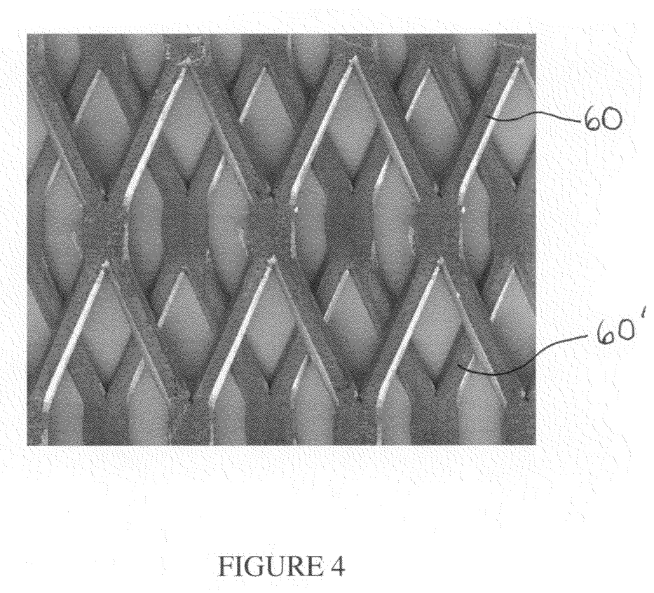

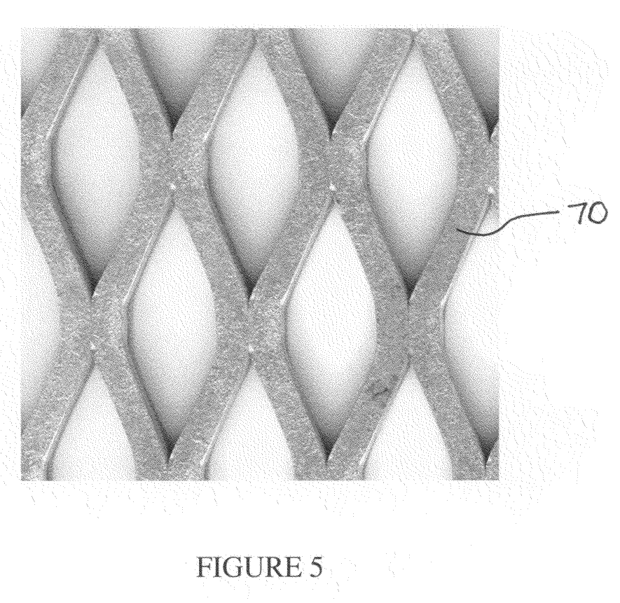

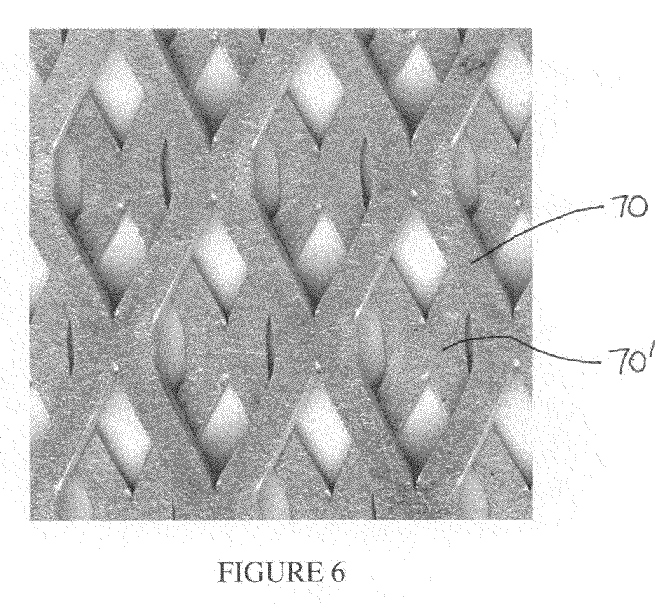

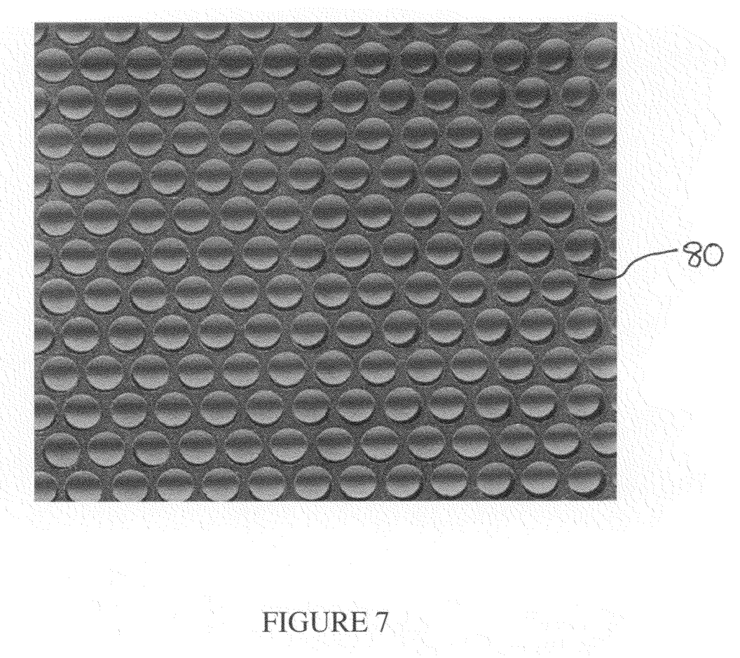

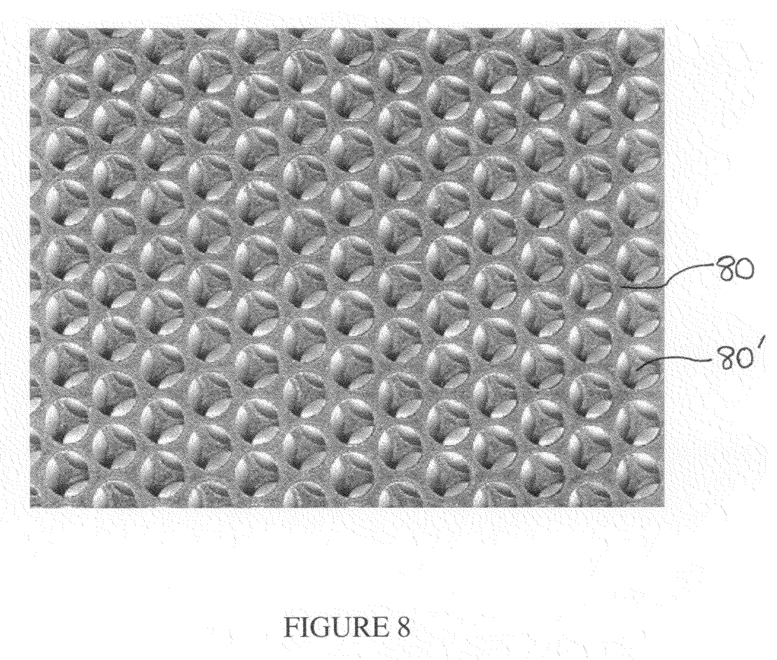

29. Turned on the power to the router 20 located within the wireless signal shielding chamber 10 and enabled the wireless LAN.
30. Turned on the laptop computer and placed it on a table ten meters away from the open top of the wireless signal shielding chamber 10 and provided no physical obstructions between the chamber 10 and the laptop.
31. Using the Windows XP software loaded on the laptop computer, enabled the 802.11 compatible wireless card to detect any available wireless networks.
32. Installed the wireless LAN control and detection software that came with the router kit onto the laptop.
33. Configured the laptop computer (not always necessary) enabling it to connect to the wireless LAN.
34. Using the control and detection software described in step 31, checked and recorded signal strength (for the open top, signal strength should be excellent with minimal attenuation).
35. Repeated step 34 twenty-nine more times.
36. Wrapped the remaining 40 cm×40 cm×7 cm CMU with 2 layers of aluminum foil.
37. Placed the non-perforated 25 cm×25 cm×0.07 cm piece of steel over the open top of the test chamber 10.
38. Carefully lifted the foil wrapped 40 cm×40 cm×7 cm CMU and placed it so as to cover the open top of the wireless signal shielding chamber.
39. Repeated steps 34 and 35 (Signal strength was zero. If signal strength is zero, proceeded to step 35. If not, lined the inside walls of the chamber with additional steel plates, and repeat steps 37 and 38).
40. Carefully removed and stored the CMU lid and steel plate from steps 33 and 34.
41. Placed the plywood substrate over the open top of the wireless signal shielding chamber 10.
42. Repeated steps 34 and 35.
43. Removed the tested substrate and set it aside.
44. Placed the gypsum board substrate over the open top of the wireless signal shielding chamber 10.
45. Repeated steps 34 and 35.
46. Removed the tested substrate and set it aside.
47. Placed the low density fiberboard substrate over the open top of the wireless signal shielding chamber 10.
48. Repeated steps 34 and 35.
49. Removed the tested substrate and set it aside.
50. Placed the fiberglass duct board substrate over the open top of the wireless signal shielding chamber 10.
51. Repeated steps 34 and 35.
52. Removed the tested substrate and set it aside.
53. Placed the vinyl mini-blinds, oriented so that they are closed, over the open top of the wireless signal shielding chamber 10.
54. Repeated steps 34 and 35.
55. Removed the tested material and set it aside.
56. Placed 1 layer of the narrow expanded aluminum over the open top of wireless signal shielding chamber 10.
57. Repeated steps 34 and 35.
58. Attached the copper wire connected to earth ground to one end of the substrate covering the wireless signal shielding chamber 10.
59. Repeated steps 34 and 35.
60. Disconnected the copper wire connected to earth ground.
61. Attached the leads for the 9 volt battery to its two (positive and negative) poles.
62. Attached the negative lead from the 9 volt battery to one corner of the substrate covering the wireless signal shielding chamber 10.
63. Attached the positive lead from the 9 volt battery to the opposite corner of the substrate covering the wireless signal shielding chamber 10.
64. Repeated steps 34 and 35.
65. Disconnected the 9 volt battery leads.
66. Placed magnets along the four outside edges of the test substrate.
67. Repeated steps 34 and 35.
68. Removed the magnets.
69. Removed the tested substrate and set it aside.
70. Placed 2 layers of the narrow expanded aluminum 60 over the open top of wireless signal shielding chamber 10 being sure to align the two layers so they are as open as possible as shown in FIG. 3.
71. Repeated steps 57-69.
72. Placed 2 layers of the narrow expanded aluminum 60 and 60′ over the open top of wireless signal shielding chamber 10 being sure to offset the two layers so they are as closed as possible as shown in FIG. 4.
73. Repeated steps 57-69.
74. Placed 1 layer of the wide expanded aluminum 70 over the open top of wireless signal shielding chamber.
75. Repeated steps 57-69.
76. Placed 2 layers of the wide expanded aluminum 70 over the open top of wireless signal shielding chamber 10 being sure to align the two layers so they are as open as possible as shown in FIG. 5.
77. Repeated steps 57-69.
78. Placed 2 layers of the wide expanded aluminum 70 and 70′ over the open top of wireless signal shielding chamber 10 being sure to offset the two layers so they are as closed as possible as shown in FIG. 6.
79. Repeated steps 57-69.
80. Placed 1 layer of the perforated steel 80 over the open top of wireless signal shielding chamber.
81. Repeated steps 57-69.
82. Placed 2 layers of the perforated steel 80 over the open top of wireless signal shielding chamber 10 being sure to align the two layers so they are as open as possible as shown in FIG. 7.
83. Repeated steps 57-69.
84. Placed 2 layers of the perforated steel 80 and 80′ over the open top of wireless signal shielding chamber 10 being sure to offset the two layers so they are as closed as possible as shown in FIG. 8.
85. Repeated steps 57-69.
86. Placed a fine aluminum mesh (not shown) over the open top of wireless signal shielding chamber 10.
87. Repeated steps 57-69.
88. Attached 1 layer of aluminum foil to the fiberglass substrate (not shown).
89. Placed the foil backed fiberglass substrate from step 88 over the open top of wireless signal shielding chamber 10 with the foil side down.
90. Repeated steps 57-69.
91. Attached 2 additional layers of aluminum foil the fiberglass substrate (not shown) from step 88 making the aluminum layer 3× thick.
92. Placed the 3× foil backed fiberglass substrate from step 91 (not shown) over the open top of wireless signal shielding chamber 10 with the foil side down.
93. Repeated steps 57-69.
94. Placed 1 layer of aluminum foil on each of the two 25 cm×25 cm outside surfaces of the fiberglass substrate so that a test specimen with two single layers of foil separated by approximately 5 cm exists (not shown).
95. Placed the double foil faced fiberglass substrate from step 94 over the open top of wireless signal shielding chamber.
96. Repeated steps 57-69.
97. Completely wrapped all sides of the low density fiberboard with a single layer of aluminum foil (not shown).
98. Placed the foil wrapped low density fiberboard substrate from step 97 over the open top of wireless signal shielding chamber.
99. Repeated steps 57-69.
100. Oriented aluminum mini-blinds (not shown) so that they were set in the closed position and placed them over the open top of the wireless signal shielding chamber 10.
101. Repeated steps 57-69.
102. Oriented the aluminum mini-blinds (not shown) so that they were set in the open position and placed them over the open top of the wireless signal shielding chamber 10.
103. Repeat steps 57-69.

The lower limit for signal strength that could be detected by the Passmark Software's WirlessMon was approximately −89 dB. If a WLAN signal was detected, but weaker than −89 dB, it would simply register as −200 dB. This reading of −200 dB indicated that a signal was present, but not strong enough to provide a reliable connection to the network. Due to this software limitation, a value of −90 dB was used throughout the course of this experiment to indicate a fully attenuated signal.

The signal detection program used throughout the experiment yielded attenuation in increments of whole units (i.e. −70 dB, −71 dB, −72 dB, etc.). In the addition to attenuation, the software used also provided readings for signal strength in terms of whole number percents (i.e. 68%, 69%, 70%, etc.). It was noted that a 2 dB change in attenuation equated to a 1% difference in signal strength, the range for signal strength being from 0 to 100% and the range for attenuation being from −200 to 0 dB. Although there should be no difference in accuracy, the expanded scale for signal attenuation meant that those readings were more precise. For this reason signal attenuation was used as the measure for test assembly performance. For each test assembly condition evaluated during the experiment, thirty consecutive signal attenuation readings were taken, one reading each second for thirty seconds. All readings were taken with the receiving device set 10 meters away from the test chamber.

In the experiment, seventy-one different test assembly conditions were evaluated. Tables 1-9 contain the individual signal attenuation values recorded for each test assembly condition evaluated, along with their respective maximum, minimum, range, average and standard deviation values.

TABLE 1

| | Assembly Description | | | | | | |
|---|---|---|---|---|---|---|---|
| | open top | | | | | Low | Vinyl |
| | fully | closed | 20 mm | Fiberglass | Gypsum | Density | Miniblinds |
| | shielded | top 10 | plywood | Insulation | Board | Fiberboard | (Closed) |
| Trial | 10 meters | meters | 10 meters | 10 meters | 10 meters | 10 meters | 10 meters |
| Number | Signal Strength Reduction (dB) | | | | | | |
| 1 | −59 | −90 | −69 | −58 | −74 | −57 | −58 |
| 2 | −63 | −90 | −70 | −57 | −64 | −58 | −59 |
| 3 | −63 | −90 | −66 | −58 | −63 | −58 | −58 |
| 4 | −62 | −90 | −67 | −67 | −67 | −59 | −59 |
| 5 | −61 | −90 | −68 | −59 | −61 | −68 | −58 |
| 6 | −63 | −90 | −68 | −59 | −65 | −56 | −60 |
| 7 | −62 | −90 | −68 | −61 | −64 | −57 | −60 |
| 8 | −62 | −90 | −68 | −61 | −63 | −59 | −60 |
| 9 | −60 | −90 | −68 | −59 | −63 | −59 | −60 |
| 10 | −61 | −90 | −65 | −66 | −66 | −65 | −60 |
| 11 | −63 | −90 | −67 | −59 | −61 | −59 | −60 |
| 12 | −62 | −90 | −66 | −59 | −61 | −56 | −57 |
| 13 | −60 | −90 | −66 | −58 | −61 | −56 | −57 |
| 14 | −64 | −90 | −72 | −59 | −68 | −64 | −59 |
| 15 | −63 | −90 | −65 | −58 | −64 | −57 | −58 |
| 16 | −62 | −90 | −65 | −58 | −70 | −55 | −59 |
| 17 | −62 | −90 | −65 | −67 | −64 | −56 | −58 |
| 18 | −62 | −90 | −68 | −58 | −64 | −61 | −60 |
| 19 | −60 | −90 | −63 | −58 | −64 | −56 | −60 |
| 20 | −61 | −90 | −64 | −58 | −63 | −62 | −61 |
| 21 | −62 | −90 | −64 | −66 | −63 | −62 | −59 |
| 22 | −62 | −90 | −70 | −67 | −64 | −56 | −58 |
| 23 | −62 | −90 | −68 | −59 | −72 | −56 | −58 |
| 24 | −61 | −90 | −65 | −59 | −66 | −56 | −57 |
| 25 | −59 | −90 | −65 | −59 | −66 | −56 | −58 |
| 26 | −59 | −90 | −70 | −66 | −67 | −63 | −58 |
| 27 | −63 | −90 | −70 | −69 | −67 | −62 | −58 |
| 28 | −62 | −90 | −66 | −69 | −65 | −57 | −57 |
| 29 | −62 | −90 | −67 | −67 | −63 | −62 | −61 |
| 30 | −62 | −90 | −69 | −56 | −61 | −57 | −58 |
| Max | −59 | −90 | −63 | −56 | −61 | −55 | −57 |
| Min | −64 | −90 | −72 | −69 | −74 | −68 | −61 |
| Range | 5 | 0 | 9 | 13 | 13 | 13 | 4 |
| Average | −61.63 | −90.00 | −67.07 | −61.13 | −64.80 | −58.83 | −58.77 |
| Std. Dev | 1.30 | 0.00 | 2.18 | 4.13 | 3.16 | 3.30 | 1.19 |

TABLE 2

| | Assembly Description | | | | | | | |
|---|---|---|---|---|---|---|---|---|
| | | | Foil | | | | Foil | |
| | | Foil | backed | Foil | | Foil | backed | Foil |
| | Foil | backed | (1 layer) | backed | Foil | backed | (3 layers) | backed |
| | backed | (1 layer) | Fiberglass | (1 layer) | backed | (3 layers) | Fiberglass | (3 layers) |
| | (1 layer) | Fiberglass | 9 V | Fiberglass | (3 layers) | Fiberglass | 9 V | Fiberglass |
| | Fiberglass | Grounded | battery 10 | Magnets | Fiberglass | Grounded | battery 10 | Magnets |
| Trial | 10 meters | 10 meters | meters | 10 meters | 10 meters | 10 meters | meters | 10 meters |
| Number | Signal Strength Reduction (dB) | | | | | | | |
| 1 | −81 | −82 | −80 | −77 | −84 | −83 | −79 | −75 |
| 2 | −83 | −82 | −80 | −82 | −84 | −83 | −79 | −75 |
| 3 | −68 | −81 | −74 | −82 | −75 | −82 | −79 | −74 |
| 4 | −81 | −81 | −74 | −78 | −75 | −81 | −81 | −76 |
| 5 | −81 | −76 | −79 | −78 | −85 | −80 | −81 | −76 |
| 6 | −71 | −77 | −79 | −79 | −82 | −80 | −79 | −76 |
| 7 | −81 | −77 | −76 | −80 | −82 | −81 | −79 | −76 |
| 8 | −70 | −77 | −80 | −74 | −75 | −81 | −78 | −79 |
| 9 | −70 | −82 | −74 | −74 | −80 | −79 | −81 | −79 |
| 10 | −70 | −83 | −79 | −80 | −81 | −81 | −79 | −77 |
| 11 | −70 | −81 | −81 | −80 | −82 | −80 | −79 | −77 |
| 12 | −69 | −81 | −78 | −79 | −82 | −80 | −81 | −81 |
| 13 | −69 | −82 | −78 | −75 | −84 | −82 | −79 | −81 |
| 14 | −81 | −73 | −78 | −80 | −83 | −82 | −80 | −80 |
| 15 | −69 | −74 | −78 | −80 | −75 | −81 | −82 | −81 |
| 16 | −69 | −74 | −80 | −73 | −75 | −82 | −81 | −74 |
| 17 | −69 | −81 | −73 | −73 | −81 | −82 | −80 | −73 |
| 18 | −70 | −82 | −73 | −77 | −80 | −82 | −80 | −82 |
| 19 | −80 | −83 | −76 | −79 | −80 | −81 | −80 | −82 |
| 20 | −77 | −80 | −75 | −83 | −79 | −82 | −77 | −76 |
| 21 | −69 | −76 | −76 | −81 | −80 | −81 | −77 | −82 |
| 22 | −70 | −76 | −85 | −79 | −81 | −82 | −77 | −79 |
| 23 | −69 | −76 | −85 | −79 | −82 | −81 | −77 | −79 |
| 24 | −69 | −76 | −76 | −79 | −82 | −81 | −79 | −74 |
| 25 | −67 | −76 | −75 | −79 | −81 | −82 | −79 | −74 |
| 26 | −82 | −82 | −77 | −80 | −76 | −82 | −78 | −77 |
| 27 | −74 | −75 | −77 | −80 | −82 | −80 | −79 | −75 |
| 28 | −74 | −75 | −84 | −74 | −82 | −81 | −80 | −81 |
| 29 | −71 | −81 | −74 | −78 | −83 | −78 | −79 | −74 |
| 30 | −85 | −79 | −75 | −79 | −76 | −78 | −80 | −78 |
| Max | −67 | −73 | −73 | −73 | −75 | −78 | −77 | −73 |
| Min | −85 | −83 | −85 | −83 | −85 | −83 | −82 | −82 |
| Range | 18 | 10 | 12 | 10 | 10 | 5 | 5 | 9 |
| Average | −73.63 | −78.70 | −77.63 | −78.37 | −80.30 | −81.03 | −79.30 | −77.43 |
| Std. Dev | 5.73 | 3.17 | 3.31 | 2.67 | 3.12 | 1.25 | 1.32 | 2.86 |

| | |
|---|---|
| Minimum critical t-stat | Minimum critical t-stat |
| for 95% confidence of | for 95% confidence of |
| a difference in these | a difference in these |
| assemblies = 7.0 | assemblies = 5.3 |

TABLE 3

| | Assembly Description | | | | | | | |
|---|---|---|---|---|---|---|---|---|
| | | | | | | | Wide | |
| | | | Wide | | | Wide | Expanded | Wide |
| | | Wide | Expanded | Wide | Wide | Expanded | Aluminum | Expanded |
| | Wide | Expanded | Aluminum | Expanded | Expanded | Aluminum | (2 layers) | Aluminum |
| | Expanded | Aluminum | (1 layer) | Aluminum | Aluminum | (2 layers) | Aligned | (2 layers) |
| | Aluminum | (1 layer) | 9 V | (1 layer) | (2 layers) | Aligned | 9 V | Aligned |
| | (1 layer) | Grounded | Battery | Magnets | Aligned | Grounded | Battery | Magnets |
| Trial | 10 meters | 10 meters | 10 meters | 10 meters | 10 meters | 10 meters | 10 meters | 10 meters |
| Number | Signal Strength Reduction (dB) | | | | | | | |
| 1 | −72 | −71 | −76 | −68 | −77 | −74 | −76 | −74 |
| 2 | −70 | −70 | −74 | −70 | −73 | −76 | −77 | −71 |
| 3 | −76 | −70 | −76 | −71 | −80 | −74 | −77 | −70 |
| 4 | −70 | −70 | −73 | −71 | −80 | −74 | −74 | −70 |
| 5 | −70 | −69 | −75 | −71 | −72 | −73 | −76 | −70 |
| 6 | −72 | −72 | −75 | −81 | −74 | −73 | −75 | −72 |
| 7 | −72 | −70 | −74 | −81 | −74 | −73 | −75 | −71 |
| 8 | −72 | −69 | −74 | −67 | −79 | −73 | −71 | −71 |
| 9 | −67 | −69 | −74 | −73 | −74 | −80 | −70 | −71 |
| 10 | −73 | −69 | −74 | −67 | −73 | −74 | −74 | −71 |
| 11 | −73 | −69 | −74 | −67 | −73 | −73 | −71 | −71 |
| 12 | −69 | −69 | −74 | −75 | −80 | −73 | −70 | −71 |
| 13 | −69 | −68 | −74 | −75 | −71 | −80 | −70 | −71 |
| 14 | −67 | −69 | −75 | −75 | −77 | −75 | −70 | −70 |
| 15 | −70 | −68 | −74 | −75 | −77 | −73 | −70 | −72 |
| 16 | −66 | −68 | −74 | −74 | −69 | −73 | −69 | −72 |
| 17 | −66 | −70 | −73 | −74 | −70 | −72 | −69 | −73 |
| 18 | −74 | −69 | −73 | −73 | −69 | −73 | −76 | −71 |
| 19 | −74 | −70 | −73 | −74 | −69 | −80 | −76 | −70 |
| 20 | −77 | −70 | −73 | −67 | −69 | −73 | −69 | −70 |
| 21 | −76 | −71 | −74 | −74 | −76 | −75 | −69 | −71 |
| 22 | −68 | −71 | −74 | −82 | −70 | −73 | −69 | −70 |
| 23 | −68 | −70 | −75 | −68 | −70 | −80 | −70 | −71 |
| 24 | −70 | −70 | −75 | −74 | −70 | −80 | −69 | −71 |
| 25 | −70 | −73 | −73 | −74 | −70 | −73 | −69 | −71 |
| 26 | −69 | −70 | −73 | −72 | −77 | −80 | −76 | −70 |
| 27 | −76 | −70 | −75 | −72 | −77 | −80 | −76 | −71 |
| 28 | −68 | −70 | −73 | −73 | −78 | −80 | −76 | −71 |
| 29 | −68 | −70 | −74 | −73 | −68 | −80 | −70 | −70 |
| 30 | −68 | −70 | −76 | −73 | −75 | −73 | −75 | −71 |
| Max | −66 | −68 | −73 | −67 | −68 | −72 | −69 | −70 |
| Min | −77 | −73 | −76 | −82 | −80 | −80 | −77 | −74 |
| Range | 11 | 5 | 3 | 15 | 12 | 8 | 8 | 4 |
| Average | −70.67 | −69.80 | −74.13 | −72.80 | −73.70 | −75.43 | −72.47 | −70.97 |
| Std. Dev | 3.12 | 1.10 | 0.94 | 3.93 | 3.84 | 3.14 | 3.13 | 0.93 |

| | |
|---|---|
| Minimum critical t-stat | Minimum critical t-stat |
| for 95% confidence of | for 95% confidence of |
| a difference in | a difference in |
| these assemblies = 2.4 | these assemblies = 5.5 |

TABLE 4

| | Assembly Description | | | | | | | |
|---|---|---|---|---|---|---|---|---|
| | | | Wide | | | | | |
| | | Wide | Expanded | Wide | | | Narrow | |
| | Wide | Expanded | Aluminum | Expanded | | Narrow | Expanded | Narrow |
| | Expanded | Aluminum | (2 layers) | Aluminum | Narrow | Expanded | Aluminum | Expanded |
| | Aluminum | (2 layers) | Offset | (2 layers) | Expanded | Aluminum | (1 layer) | Aluminum |
| | (2 layers) | Offset | 9 V | Offset | Aluminum | (1 layer) | 9 V | (1 layer) |
| | Offset | Grounded | Battery | Magnets | (1 layer) | Grounded | Battery | Magnets |
| Trial | 10 meters | 10 meters | 10 meters | 10 meters | 10 meters | 10 meters | 10 meters | 10 meters |
| Number | Signal Strength Reduction (dB) | | | | | | | |
| 1 | −75 | −79 | −76 | −76 | −74 | −73 | −71 | −66 |
| 2 | −75 | −78 | −76 | −76 | −72 | −73 | −72 | −67 |
| 3 | −75 | −80 | −81 | −76 | −72 | −72 | −73 | −67 |
| 4 | −76 | −79 | −82 | −75 | −74 | −72 | −74 | −75 |
| 5 | −80 | −77 | −81 | −75 | −70 | −77 | −74 | −68 |
| 6 | −79 | −79 | −81 | −74 | −72 | −77 | −77 | −68 |
| 7 | −79 | −79 | −78 | −74 | −72 | −73 | −73 | −75 |
| 8 | −78 | −82 | −78 | −76 | −72 | −73 | −73 | −75 |
| 9 | −74 | −79 | −79 | −76 | −72 | −73 | −72 | −66 |
| 10 | −74 | −82 | −78 | −76 | −72 | −73 | −72 | −75 |
| 11 | −82 | −82 | −77 | −76 | −73 | −71 | −71 | −75 |
| 12 | −82 | −82 | −76 | −77 | −73 | −72 | −71 | −66 |
| 13 | −79 | −77 | −77 | −75 | −71 | −74 | −73 | −75 |
| 14 | −79 | −78 | −77 | −76 | −69 | −74 | −72 | −66 |
| 15 | −80 | −77 | −76 | −76 | −69 | −72 | −73 | −66 |
| 16 | −80 | −82 | −82 | −76 | −71 | −73 | −72 | −66 |
| 17 | −76 | −77 | −76 | −76 | −70 | −74 | −72 | −75 |
| 18 | −80 | −79 | −76 | −77 | −70 | −74 | −72 | −66 |
| 19 | −80 | −79 | −76 | −77 | −70 | −72 | −72 | −66 |
| 20 | −80 | −84 | −76 | −78 | −73 | −72 | −72 | −73 |
| 21 | −80 | −82 | −75 | −76 | −73 | −74 | −71 | −73 |
| 22 | −80 | −78 | −75 | −79 | −71 | −72 | −70 | −68 |
| 23 | −76 | −78 | −77 | −79 | −71 | −72 | −71 | −68 |
| 24 | −80 | −81 | −76 | −79 | −71 | −71 | −71 | −67 |
| 25 | −77 | −81 | −75 | −76 | −71 | −72 | −70 | −73 |
| 26 | −77 | −83 | −75 | −77 | −70 | −72 | −72 | −73 |
| 27 | −80 | −82 | −74 | −77 | −70 | −72 | −71 | −73 |
| 28 | −75 | −79 | −77 | −77 | −72 | −73 | −70 | −68 |
| 29 | −77 | −79 | −77 | −76 | −70 | −71 | −71 | −68 |
| 30 | −80 | −82 | −77 | −79 | −73 | −71 | −71 | −73 |
| Max | −74 | −77 | −74 | −74 | −69 | −71 | −70 | −66 |
| Min | −82 | −84 | −82 | −79 | −74 | −77 | −77 | −75 |
| Range | 8 | 7 | 8 | 5 | 5 | 6 | 7 | 9 |
| Average | −78.17 | −79.87 | −77.23 | −76.43 | −71.43 | −72.80 | −71.97 | −70.00 |
| Std. Dev | 2.36 | 2.03 | 2.18 | 1.33 | 1.38 | 1.47 | 1.43 | 3.75 |

| | |
|---|---|
| Minimum critical t-stat | Minimum critical t-stat |
| for 95% confidence of | for 95% confidence of |
| a difference in | a difference in |
| these assemblies = 4.1 | these assemblies = 3.4 |

TABLE 5

| | Assembly Description | | | | | | | |
|---|---|---|---|---|---|---|---|---|
| | | | Narrow | | | | Narrow | |
| | | Narrow | Expanded | Narrow | | Narrow | Expanded | Narrow |
| | Narrow | Expanded | Aluminum | Expanded | Narrow | Expanded | Aluminum | Expanded |
| | Expanded | Aluminum | (2 layers) | Aluminum | Expanded | Aluminum | (2 layers) | Aluminum |
| | Aluminum | (2 layers) | Aligned | (2 layers) | Aluminum | (2 layers) | Offset | (2 layers) |
| | (2 layers) | Aligned | 9 V | Aligned | (2 layers) | Offset | 9 V | Offset |
| | Aligned | Grounded | Battery | Magnets | Offset | Grounded | Battery | Magnets |
| Trial | 10 meters | 10 meters | 10 meters | 10 meters | 10 meters | 10 meters | 10 meters | 10 meters |
| Number | Signal Strength Reduction (dB) | | | | | | | |
| 1 | −83 | −77 | −73 | −74 | −75 | −79 | −79 | −71 |
| 2 | −76 | −77 | −80 | −76 | −76 | −80 | −79 | −76 |
| 3 | −79 | −76 | −80 | −70 | −76 | −79 | −80 | −83 |
| 4 | −78 | −76 | −73 | −71 | −75 | −79 | −79 | −83 |
| 5 | −70 | −76 | −81 | −75 | −75 | −79 | −79 | −73 |
| 6 | −70 | −75 | −71 | −70 | −78 | −79 | −80 | −76 |
| 7 | −70 | −76 | −71 | −70 | −78 | −81 | −79 | −76 |
| 8 | −76 | −73 | −71 | −69 | −75 | −80 | −79 | −73 |
| 9 | −71 | −77 | −71 | −76 | −75 | −80 | −79 | −76 |
| 10 | −80 | −77 | −82 | −76 | −76 | −80 | −79 | −76 |
| 11 | −80 | −76 | −73 | −76 | −79 | −79 | −80 | −74 |
| 12 | −79 | −76 | −79 | −76 | −77 | −79 | −80 | −74 |
| 13 | −80 | −76 | −79 | −70 | −77 | −80 | −80 | −73 |
| 14 | −69 | −79 | −71 | −74 | −76 | −80 | −80 | −73 |
| 15 | −70 | −75 | −71 | −70 | −76 | −79 | −79 | −73 |
| 16 | −69 | −75 | −80 | −70 | −77 | −79 | −80 | −73 |
| 17 | −80 | −76 | −82 | −71 | −79 | −79 | −79 | −75 |
| 18 | −70 | −75 | −69 | −70 | −77 | −79 | −79 | −75 |
| 19 | −70 | −75 | −69 | −70 | −77 | −80 | −80 | −75 |
| 20 | −76 | −77 | −83 | −73 | −77 | −80 | −79 | −74 |
| 21 | −70 | −76 | −82 | −72 | −78 | −80 | −79 | −74 |
| 22 | −78 | −76 | −76 | −71 | −74 | −80 | −79 | −74 |
| 23 | −78 | −80 | −82 | −71 | −74 | −79 | −80 | −82 |
| 24 | −70 | −80 | −80 | −74 | −80 | −80 | −80 | −82 |
| 25 | −71 | −75 | −81 | −74 | −74 | −80 | −80 | −73 |
| 26 | −79 | −75 | −73 | −74 | −80 | −80 | −80 | −73 |
| 27 | −77 | −75 | −73 | −70 | −80 | −80 | −79 | −74 |
| 28 | −79 | −75 | −83 | −73 | −73 | −79 | −79 | −74 |
| 29 | −70 | −76 | −82 | −73 | −73 | −80 | −80 | −74 |
| 30 | −80 | −73 | −79 | −70 | −78 | −80 | −79 | −74 |
| Max | −69 | −73 | −69 | −69 | −73 | −79 | −79 | −71 |
| Min | −83 | −80 | −83 | −76 | −80 | −81 | −80 | −83 |
| Range | 14 | 7 | 14 | 7 | 7 | 2 | 1 | 12 |
| Average | −74.93 | −76.03 | −76.67 | −72.30 | −76.50 | −79.60 | −79.43 | −75.20 |
| Std. Dev | 4.61 | 1.59 | 4.91 | 2.37 | 2.00 | 0.56 | 0.50 | 3.14 |

| | |
|---|---|
| Critical t-stat for 95% | Critical t-stat for 95% |
| confidence of a | confidence of a |
| difference in these | difference in these |
| assemblies = 4.8 | assemblies = 1.3, 3.5 |
| | and 5.4 |

TABLE 6

| | Assembly Description | | | | | | | |
|---|---|---|---|---|---|---|---|---|
| | | | | | | | Perforated | |
| | | | Perforated | | | Perforated | Steel | Perforated |
| | | Perforated | Steel | Perforated | Perforated | Steel | (2 layers) | Steel |
| | Perforated | Steel | (1 layer) | Steel | Steel | (2 layers) | Aligned | (2 layers) |
| | Steel | (1 layer) | 9 V | (1 layer) | (2 layers) | Aligned | 9 V | Aligned |
| | (1 layer) | Grounded | Battery | Magnets | Aligned | Grounded | Battery | Magnets |
| Trial | 10 meters | 10 meters | 10 meters | 10 meters | 10 meters | 10 meters | 10 meters | 10 meters |
| Number | Signal Strength Reduction (dB) | | | | | | | |
| 1 | −86 | −83 | −82 | −85 | −84 | −84 | −84 | −82 |
| 2 | −86 | −83 | −83 | −85 | −82 | −84 | −84 | −82 |
| 3 | −77 | −84 | −84 | −85 | −82 | −84 | −85 | −82 |
| 4 | −79 | −84 | −83 | −85 | −83 | −85 | −86 | −82 |
| 5 | −87 | −83 | −83 | −85 | −83 | −86 | −85 | −86 |
| 6 | −86 | −82 | −83 | −85 | −82 | −85 | −85 | −86 |
| 7 | −80 | −84 | −83 | −85 | −82 | −85 | −85 | −81 |
| 8 | −79 | −84 | −83 | −84 | −85 | −85 | −85 | −83 |
| 9 | −79 | −83 | −83 | −86 | −85 | −84 | −85 | −82 |
| 10 | −79 | −83 | −83 | −86 | −85 | −84 | −85 | −82 |
| 11 | −79 | −83 | −83 | −87 | −85 | −85 | −86 | −84 |
| 12 | −81 | −83 | −83 | −87 | −81 | −85 | −86 | −82 |
| 13 | −81 | −83 | −83 | −87 | −81 | −84 | −84 | −82 |
| 14 | −77 | −83 | −83 | −86 | −82 | −83 | −86 | −81 |
| 15 | −76 | −81 | −85 | −87 | −83 | −83 | −87 | −81 |
| 16 | −76 | −81 | −83 | −87 | −82 | −85 | −85 | −82 |
| 17 | −87 | −82 | −83 | −86 | −82 | −85 | −86 | −86 |
| 18 | −78 | −82 | −84 | −84 | −80 | −84 | −87 | −83 |
| 19 | −78 | −82 | −84 | −84 | −85 | −84 | −85 | −83 |
| 20 | −84 | −82 | −84 | −84 | −82 | −83 | −86 | −83 |
| 21 | −77 | −82 | −84 | −86 | −83 | −83 | −86 | −82 |
| 22 | −77 | −83 | −85 | −83 | −83 | −84 | −86 | −82 |
| 23 | −78 | −83 | −85 | −83 | −82 | −83 | −85 | −83 |
| 24 | −87 | −83 | −84 | −85 | −80 | −83 | −85 | −86 |
| 25 | −77 | −83 | −84 | −83 | −80 | −84 | −85 | −82 |
| 26 | −77 | −83 | −83 | −84 | −80 | −85 | −85 | −82 |
| 27 | −86 | −82 | −84 | −84 | −83 | −83 | −85 | −82 |
| 28 | −84 | −82 | −84 | −84 | −83 | −85 | −85 | −86 |
| 29 | −79 | −83 | −84 | −84 | −83 | −83 | −85 | −87 |
| 30 | −85 | −83 | −84 | −83 | −83 | −83 | −85 | −83 |
| Max | −76 | −81 | −82 | −83 | −80 | −83 | −84 | −81 |
| Min | −87 | −84 | −85 | −87 | −85 | −86 | −87 | −87 |
| Range | 11 | 3 | 3 | 4 | 5 | 3 | 3 | 6 |
| Average | −80.73 | −82.73 | −83.53 | −84.97 | −82.53 | −84.10 | −85.30 | −83.00 |
| Std. Dev | 3.89 | 0.78 | 0.73 | 1.30 | 1.53 | 0.88 | 0.75 | 1.74 |

| | |
|---|---|
| Critical t-stat for 95% | Critical t-stat for 95% |
| confidence of a | confidence of a |
| difference in these | difference in these |
| assemblies = 1.8, 2.6 | assemblies = 2.0 and |
| and 7.0 | 3.0 |

TABLE 7

| | Assembly Description | | | | | | | |
|---|---|---|---|---|---|---|---|---|
| | | | Perforated | | | | | |
| | | Perforated | Steel | Perforated | | | Fine | |
| | Perforated | Steel | (2 layers) | Steel | | Fine | Aluminum | Fine |
| | Steel | (2 layers) | Offset | (2 layers) | Fine | Aluminum | Mesh | Aluminum |
| | (2 layers) | Offset | 9 V | Offset | Aluminum | Mesh | 9 V | Mesh |
| | Offset | Grounded | Battery | Magnets | Mesh | Grounded | Battery | Magnets |
| Trial | 10 meters | 10 meters | 10 meters | 10 meters | 10 meters | 10 Meters | 10 Meters | 10 Meters |
| Number | Signal Strength Reduction (dB) | | | | | | | |
| 1 | −87 | −84 | −86 | −81 | −82 | −76 | −83 | −86 |
| 2 | −84 | −83 | −86 | −81 | −80 | −77 | −85 | −85 |
| 3 | −83 | −84 | −86 | −81 | −73 | −76 | −85 | −75 |
| 4 | −86 | −84 | −86 | −82 | −73 | −79 | −86 | −74 |
| 5 | −84 | −83 | −86 | −83 | −73 | −79 | −85 | −74 |
| 6 | −84 | −83 | −86 | −83 | −73 | −80 | −84 | −83 |
| 7 | −85 | −85 | −84 | −82 | −84 | −80 | −84 | −81 |
| 8 | −85 | −86 | −86 | −84 | −80 | −81 | −83 | −82 |
| 9 | −86 | −87 | −84 | −83 | −81 | −79 | −84 | −82 |
| 10 | −87 | −86 | −85 | −82 | −84 | −79 | −85 | −82 |
| 11 | −86 | −86 | −86 | −82 | −74 | −79 | −85 | −82 |
| 12 | −86 | −86 | −85 | −83 | −74 | −79 | −85 | −84 |
| 13 | −86 | −87 | −86 | −85 | −80 | −83 | −84 | −76 |
| 14 | −86 | −85 | −84 | −82 | −82 | −81 | −83 | −83 |
| 15 | −86 | −85 | −84 | −82 | −81 | −82 | −83 | −84 |
| 16 | −86 | −87 | −83 | −82 | −81 | −79 | −83 | −75 |
| 17 | −86 | −86 | −84 | −82 | −74 | −80 | −84 | −74 |
| 18 | −88 | −86 | −83 | −84 | −74 | −79 | −85 | −85 |
| 19 | −88 | −85 | −83 | −82 | −74 | −79 | −85 | −75 |
| 20 | −88 | −85 | −84 | −83 | −82 | −79 | −85 | −82 |
| 21 | −88 | −86 | −85 | −82 | −75 | −79 | −84 | −82 |
| 22 | −88 | −86 | −85 | −82 | −77 | −79 | −84 | −75 |
| 23 | −88 | −86 | −85 | −81 | −73 | −79 | −85 | −85 |
| 24 | −88 | −85 | −85 | −82 | −73 | −80 | −84 | −74 |
| 25 | −88 | −85 | −84 | −82 | −83 | −79 | −84 | −75 |
| 26 | −88 | −86 | −86 | −82 | −83 | −79 | −84 | −85 |
| 27 | −88 | −85 | −85 | −82 | −87 | −79 | −84 | −85 |
| 28 | −90 | −86 | −86 | −83 | −87 | −79 | −84 | −75 |
| 29 | −90 | −86 | −85 | −82 | −82 | −79 | −84 | −81 |
| 30 | −90 | −85 | −86 | −82 | −81 | −80 | −83 | −74 |
| Max | −83 | −83 | −83 | −81 | −73 | −76 | −83 | −74 |
| Min | −90 | −87 | −86 | −85 | −87 | −83 | −86 | −86 |
| Range | 7 | 4 | 3 | 4 | 14 | 7 | 3 | 12 |
| Average | −86.77 | −85.30 | −84.97 | −82.30 | −78.67 | −79.27 | −84.20 | −79.83 |
| Std. Dev | 1.81 | 1.12 | 1.03 | 0.92 | 4.63 | 1.41 | 0.81 | 4.48 |

| | |
|---|---|
| Critical t-stat for 95% | Critical t-stat for 95% |
| confidence of a | confidence of a |
| difference in these | difference in these |
| assemblies = 2.3 | assemblies = 2.8 and |
| | 7.7 |

TABLE 8

| | Assembly Description | | | | | | | |
|---|---|---|---|---|---|---|---|---|
| | | | Aluminum | | | | Aluminum | |
| | | Aluminum | Miniblinds | Aluminum | | Aluminum | Miniblinds | Aluminum |
| | Aluminum | Miniblinds | (Open) | Miniblinds | Aluminum | Miniblinds | (Closed) | Miniblinds |
| | Miniblinds | (Open) | 9 V | (Open) | Miniblinds | (Closed) | 9 V | (Closed) |
| | (Open) | Grounded | Battery | Magnets | (Closed) | Grounded | Battery | Magnets |
| Trial | 10 meters | 10 meters | 10 meters | 10 meters | 10 meters | 10 meters | 10 meters | 10 meters |
| Number | Signal Strength Reduction (dB) | | | | | | | |
| 1 | −74 | −72 | −63 | −65 | −70 | −78 | −78 | −76 |
| 2 | −74 | −68 | −64 | −67 | −70 | −83 | −77 | −83 |
| 3 | −69 | −68 | −65 | −67 | −78 | −84 | −78 | −86 |
| 4 | −73 | −67 | −65 | −67 | −72 | −84 | −77 | −76 |
| 5 | −60 | −67 | −65 | −73 | −70 | −83 | −77 | −76 |
| 6 | −60 | −66 | −65 | −68 | −70 | −83 | −81 | −83 |
| 7 | −65 | −66 | −69 | −69 | −69 | −77 | −81 | −75 |
| 8 | −73 | −65 | −68 | −67 | −69 | −84 | −77 | −83 |
| 9 | −70 | −65 | −65 | −70 | −70 | −81 | −81 | −83 |
| 10 | −64 | −67 | −70 | −67 | −77 | −81 | −79 | −84 |
| 11 | −68 | −67 | −64 | −67 | −76 | −82 | −79 | ,−74 |
| 12 | −68 | −71 | −64 | −67 | −76 | −82 | −78 | −75 |
| 13 | −69 | −65 | −70 | −66 | −77 | −76 | −78 | −75 |
| 14 | −67 | −66 | −64 | −66 | −71 | −83 | −80 | −86 |
| 15 | −62 | −66 | −68 | −66 | −70 | −78 | −78 | −83 |
| 16 | −64 | −73 | −68 | −66 | −77 | −78 | −79 | −84 |
| 17 | −63 | −67 | −64 | −67 | −77 | −82 | −79 | −84 |
| 18 | −63 | −72 | −69 | −65 | −79 | −75 | −80 | −84 |
| 19 | −62 | −73 | −70 | −68 | −70 | −80 | −80 | −74 |
| 20 | −62 | −71 | −70 | −66 | −70 | −83 | −81 | −82 |
| 21 | −59 | −73 | −65 | −65 | −70 | −80 | −81 | −82 |
| 22 | −70 | −68 | −65 | −66 | −78 | −83 | −78 | −82 |
| 23 | −70 | −68 | −65 | −66 | −71 | −78 | −78 | −74 |
| 24 | −63 | −72 | −65 | −66 | −71 | −78 | −78 | −83 |
| 25 | −60 | −71 | −65 | −65 | −70 | −81 | −82 | −83 |
| 26 | −60 | −67 | −70 | −66 | −76 | −82 | −81 | −82 |
| 27 | −65 | −67 | −70 | −66 | −71 | −83 | −83 | −86 |
| 28 | −65 | −71 | −70 | −67 | −70 | −83 | −78 | −73 |
| 29 | −65 | −71 | −66 | −66 | −74 | −82 | −86 | −73 |
| 30 | −64 | −68 | −66 | −65 | −74 | −81 | −79 | −84 |
| Max | −59 | −65 | −63 | −65 | −69 | −75 | −77 | −73 |
| Min | −74 | −73 | −70 | −73 | −79 | −84 | −86 | −86 |
| Range | 15 | 8 | 7 | 8 | 10 | 9 | 9 | 13 |
| Average | −65.70 | −68.60 | −66.57 | −66.73 | −72.77 | −80.93 | −79.40 | −80.48 |
| Std. Dev | 4.48 | 2.67 | 2.43 | 1.66 | 3.35 | 2.55 | 2.04 | 4.45 |

| | |
|---|---|
| Critical t-stat for 95% | Critical t-stat for 95% |
| confidence of a | confidence of a |
| difference in these | difference in these |
| assemblies = 5.0 | assemblies = 5.5 |
| | and 7.1 |

TABLE 9

| | Assembly Description | | | | | | | |
|---|---|---|---|---|---|---|---|---|
| | | | Low | | | | | |
| | | Low | Density | Low | | | Foil | |
| | Low | Density | Fiberboard | Density | | Foil | Covered | Foil |
| | Density | Fiberboard | Foil | Fiberboard | Foil | Covered | (outer | Covered |
| | Fiberboard | Foil | wrapped | Foil | Covered | (outer | surfaces) | (outer |
| | Foil | wrapped | 9 V | wrapped | (outer | surfaces) | Fiberglass | surfaces) |
| | wrapped | Grounded | Battery | magnets | surfaces) | Fiberglass | 9 V | Fiberglass |
| Trial | 10 meters | 10 meters | 10 meters | 10 meters | Fiberglass | Grounded | battery 10 | Magnets |
| Number | Signal Strength Reduction (dB) | | | | 10 meters | 10 meters | meters | 10 meters |
| 1 | −81 | −88 | −83 | −83 | −81 | −82 | −87 | −86 |
| 2 | −82 | −86 | −84 | −87 | −81 | −82 | −90 | −83 |
| 3 | −82 | −86 | −83 | −85 | −82 | −81 | −90 | −80 |
| 4 | −75 | −86 | −85 | −86 | −84 | −82 | −90 | −80 |
| 5 | −75 | −86 | −87 | −86 | −80 | −82 | −90 | −83 |
| 6 | −74 | −87 | −84 | −87 | −79 | −83 | −90 | −83 |
| 7 | −81 | −86 | −83 | −86 | −79 | −83 | −90 | −83 |
| 8 | −82 | −85 | −77 | −87 | −81 | −83 | −90 | −83 |
| 9 | −82 | −85 | −77 | −86 | −83 | −82 | −90 | −84 |
| 10 | −79 | −86 | −86 | −87 | −79 | −82 | −90 | −85 |
| 11 | −79 | −86 | −87 | −86 | −79 | −81 | −90 | −86 |
| 12 | −77 | −87 | −86 | −87 | −80 | −82 | −90 | −85 |
| 13 | −79 | −87 | −86 | −87 | −77 | −82 | −90 | −85 |
| 14 | −79 | −87 | −88 | −87 | −78 | −82 | −90 | −86 |
| 15 | −79 | −87 | −86 | −86 | −82 | −82 | −90 | −87 |
| 16 | −79 | −87 | −77 | −86 | −81 | −82 | −90 | −87 |
| 17 | −79 | −87 | −77 | −86 | −81 | −82 | −90 | −82 |
| 18 | −79 | −87 | −86 | −86 | −79 | −81 | −90 | −86 |
| 19 | −83 | −87 | −87 | −87 | −79 | −82 | −90 | −86 |
| 20 | −79 | −87 | −87 | −87 | −79 | −81 | −90 | −86 |
| 21 | −79 | −87 | −87 | −87 | −79 | −82 | −90 | −85 |
| 22 | −80 | −87 | −77 | −87 | −79 | −83 | −90 | −86 |
| 23 | −80 | −87 | −77 | −87 | −79 | −82 | −90 | −85 |
| 24 | −83 | −90 | −87 | −87 | −82 | −83 | −90 | −86 |
| 25 | −84 | −90 | −75 | −87 | −82 | −83 | −90 | −87 |
| 26 | −80 | −90 | −85 | −87 | −81 | −81 | −90 | −86 |
| 27 | −84 | −90 | −83 | −90 | −82 | −81 | −90 | −85 |
| 28 | −79 | −90 | −86 | −90 | −81 | −81 | −90 | −87 |
| 29 | −79 | −90 | −86 | −90 | −81 | −81 | −90 | −87 |
| 30 | −78 | −90 | −86 | −90 | −80 | −82 | −90 | −86 |
| Max | −74 | −85 | −75 | −83 | −77 | −81 | −87 | −80 |
| Min | −84 | −90 | −88 | −90 | −84 | −83 | −90 | −87 |
| Range | 10 | 5 | 13 | 7 | 7 | 2 | 3 | 7 |
| Average | −79.70 | −87.37 | −83.50 | −86.90 | −80.33 | −81.93 | −89.90 | −84.87 |
| Std. Dev | 2.47 | 1.61 | 4.05 | 1.49 | 1.58 | 0.69 | 0.55 | 1.94 |

| | |
|---|---|
| Critical t-stat for 95% | Critical t-stat for 95% |
| confidence of a | confidence of a |
| difference in these | difference in these |
| assemblies = 3.8, 4.9 | assemblies = 2.94 and |
| and 7.9 | 4.26 |

Table 10 is a summary table listing each of the test assemblies evaluated, the average attenuation in signal strength caused by that assembly, the standard deviations associated with said attenuation, and the absolute reduction in signal strength. This latter value was obtained by subtracting the attenuation yielded by an individual test assembly from the attenuation measured when the top of the chamber was left open.

TABLE 10

| | | | | Signal |
|---|---|---|---|---|
| | | Average | | Strength |
| | | Attenuation | Std. Dev | Reduction |
| Assembly Number and Description | | (dB) | (dB) | (dB) |
| 1 | open top fully shielded 10 meters | −61.6 | 1.11 | 0.0 |
| 2 | closed top 10 meters | −90.0 | 0.00 | 28.4 |
| 3 | 20 mm plywood 10 meters | −67.1 | 2.18 | 5.5 |
| 4 | Fiberglass Insulation 10 meters | −61.1 | 4.13 | 0.5 |
| 5 | Gypsum Board 10 meters | −64.8 | 3.16 | 3.2 |
| 6 | Low Density Fiberboard 10 meters | −58.8 | 3.30 | 2.8 |
| 7 | Vinyl Miniblinds (Closed) 10 meters | −58.8 | 1.19 | 2.8 |
| 8 | Foil backed (1 layer) Fiberglass 10 meters | −73.6 | 5.73 | 12.0 |
| 9 | Foil backed (1 layer) Fiberglass Grounded 10 meters | −78.7 | 3.17 | 17.1 |
| 10 | Foil backed (1 layer) Fiberglass 9 V battery 10 meters | −77.6 | 3.31 | 16.0 |
| 11 | Foil backed (1 layer) Fiberglass Magnets 10 meters | −78.4 | 2.67 | 16.8 |
| 12 | Foil backed (3 layers) Fiberglass 10 meters | −80.3 | 3.12 | 18.7 |
| 13 | Foil backed (3 layers) Fiberglass Grounded 10 meters | −81.0 | 1.25 | 19.4 |
| 14 | Foil backed (3 layers) Fiberglass 9 V battery 10 meters | −79.3 | 1.32 | 17.7 |
| 15 | Foil backed (3 layers) Fiberglass Magnets 10 meters | −77.4 | 2.86 | 15.8 |
| 16 | Wide Expanded Aluminum (1 layer) 10 meters | −70.7 | 3.12 | 9.1 |
| 17 | Wide Expanded Aluminum (1 layer) Grounded 10 meters | −69.8 | 1.10 | 8.2 |
| 18 | Wide Expanded Aluminum (1 layer) 9 V Battery 10 meters | −74.1 | 0.94 | 12.5 |
| 19 | Wide Expanded Aluminum (1 layer) Magnets 10 meters | −72.8 | 3.93 | 11.2 |
| 20 | Wide Expanded Aluminum (2 layers) Aligned 10 meters | −73.7 | 3.84 | 12.1 |
| 21 | Wide Expanded Aluminum (2 layers) Aligned Grounded 10 | −75.4 | 3.14 | 13.8 |
| | meters | | | |
| 22 | Wide Expanded Aluminum (2 layers) Aligned 9 V Battery 10 | −72.5 | 3.13 | 10.9 |
| | meters | | | |
| 23 | Wide Expanded Aluminum (2 layers) Aligned Magnets 10 | −71.0 | 0.93 | 9.4 |
| | meters | | | |
| 24 | Wide Expanded Aluminum (2 layers) Offset 10 meters | −78.2 | 2.36 | 16.6 |
| 25 | Wide Expanded Aluminum (2 layers) Offset Grounded 10 meters | −79.9 | 2.03 | 18.3 |
| 26 | Wide Expanded Aluminum (2 layers) Offset 9 V Battery 10 | −77.2 | 2.18 | 15.6 |
| | meters | | | |
| 27 | Wide Expanded Aluminum (2 layers) Offset Magnets 10 meters | −76.4 | 1.33 | 14.8 |
| 28 | Narrow Expanded Aluminum (1 layer) 10 meters | −71.4 | 1.38 | 9.8 |
| 29 | Narrow Expanded Aluminum (1 layer) Grounded 10 meters | −72.8 | 1.47 | 11.2 |
| 30 | Narrow Expanded Aluminum (1 layer) 9 V Battery 10 meters | −72.0 | 1.43 | 10.4 |
| 31 | Narrow Expanded Aluminum (1 layer) Magnets 10 meters | −70.0 | 3.75 | 8.4 |
| 32 | Narrow Expanded Aluminum (2 layers) Aligned 10 meters | −74.9 | 4.61 | 13.3 |
| 33 | Narrow Expanded Aluminum (2 layers) Aligned Grounded 10 | −76.0 | 1.59 | 14.4 |
| | meters | | | |
| 34 | Narrow Expanded Aluminum (2 layers) Aligned 9 V Battery 10 | −76.7 | 4.91 | 15.1 |
| | meters | | | |
| 35 | Narrow Expanded Aluminum (2 layers) Aligned Magnets 10 | −72.3 | 2.37 | 10.7 |
| | meters | | | |
| 36 | Narrow Expanded Aluminum (2 layers) Offset 10 meters | −76.5 | 2.00 | 12.0 |
| 37 | Narrow Expanded Aluminum (2 layers) Offset Grounded 10 | −79.6 | 0.56 | 15.1 |
| | meters | | | |
| 38 | Narrow Expanded Aluminum (2 layers) Offset 9 V Battery 10 | −79.4 | 0.50 | 14.9 |
| | meters | | | |
| 39 | Narrow Expanded Aluminum (2 layers) Offset Magnets 10 | −75.2 | 3.14 | 10.7 |
| | meters | | | |
| 40 | Perforated Steel (1 layer) 10 meters | −80.7 | 3.89 | 16.2 |
| 41 | Perforated Steel (1 layer) Grounded 10 meters | −82.7 | 0.78 | 18.2 |
| 42 | Perforated Steel (1 layer) 9 V Battery 10 meters | −83.5 | 0.73 | 19.0 |
| 43 | Perforated Steel (1 layer) Magnets 10 meters | −85.0 | 1.30 | 20.5 |
| 44 | Perforated Steel (2 layers) Aligned 10 meters | −82.5 | 1.53 | 18.0 |
| 45 | Perforated Steel (2 layers) Aligned Grounded 10 meters | −84.1 | 0.88 | 19.6 |
| 46 | Perforated Steel (2 layers) Aligned 9 V Battery 10 meters | −85.3 | 0.75 | 20.8 |
| 47 | Perforated Steel (2 layers) Aligned Magnets 10 meters | −83.0 | 1.74 | 18.5 |
| 48 | Perforated Steel (2 layers) Offset 10 meters | −86.8 | 1.81 | 22.3 |
| 49 | Perforated Steel (2 layers) Offset Grounded 10 meters | −85.3 | 1.12 | 20.8 |
| 50 | Perforated Steel (2 layers) Offset 9 V Battery 10 meters | −85.0 | 1.03 | 20.5 |
| 51 | Perforated Steel (2 layers) Offset Magnets 10 meters | −82.3 | 0.92 | 17.8 |
| 52 | Fine Aluminum Mesh 10 Meters | −78.7 | 4.63 | 14.2 |
| 53 | Fine Aluminum Mesh Grounded 10 Meters | −79.3 | 1.41 | 14.8 |
| 54 | Fine Aluminum Mesh 9 V Battery 10 Meters | −84.2 | 0.81 | 19.7 |
| 55 | Fine Aluminum Mesh Magnets 10 Meters | −79.8 | 4.48 | 15.3 |
| 56 | Aluminum Miniblinds (Open) 10 meters | −65.7 | 4.48 | 1.2 |
| 57 | Aluminum Miniblinds (Open) Grounded 10 meters | −68.6 | 2.67 | 4.1 |
| 58 | Aluminum Miniblinds (Open) 9 V Battery 10 meters | −66.6 | 2.43 | 2.1 |
| 59 | Aluminum Miniblinds (Open) Magnets 10 meters | −66.7 | 1.66 | 2.2 |
| 60 | Aluminum Miniblinds (Closed) 10 meters | −72.8 | 3.35 | 8.3 |
| 61 | Aluminum Miniblinds (Closed) Grounded 10 meters | −80.9 | 2.55 | 16.4 |
| 62 | Aluminum Miniblinds (Closed) 9 V Battery 10 meters | −79.4 | 2.04 | 14.9 |
| 63 | Aluminum Miniblinds (Closed) Magnets 10 meters | −80.5 | 4.45 | 16.0 |
| 64 | Low Density Fiberboard Foil wrapped 10 meters | −79.7 | 2.47 | 15.2 |
| 65 | Low Density Fiberboard Foil wrapped Grounded 10 meters | −87.4 | 1.61 | 22.9 |
| 66 | Low Density Fiberboard Foil wrapped 9 V Battery 10 meters | −83.5 | 4.05 | 19.0 |
| 67 | Low Density Fiberboard Foil wrapped magnets 10 meters | −86.9 | 1.49 | 22.4 |
| 68 | Foil Covered (outer surfaces) Fiberglass 10 meters | −80.3 | 1.58 | 15.8 |
| 69 | Foil Covered (outer surfaces) Fiberglass Grounded 10 meters | −81.9 | 0.69 | 17.4 |
| 70 | Foil Covered (outer surfaces) Fiberglass 9 V battery 10 meters | −89.9 | 0.55 | 25.4 |
| 71 | Foil Covered (outer surfaces) Fiberglass Magnets 10 meters | −84.9 | 1.94 | 20.4 |

Three of the seventy-one test assemblies evaluated actually yielded negative attenuations, implying enhanced signal strength compared to the open top rather than a reduction. The differences are small (<3 dB), and were not found to be statistically significant. This indicates that the negative attenuations were the result of experimental error, and that the assemblies provide essentially zero attenuation.

Table 11 shows the average attenuations and standard deviations for all of the conductors and non-conductors evaluated during this experiment. For the non-conductors these values were collected with the test assemblies floating electrically. For the conductors, the average attenuations and standard deviations are shown for the assemblies when they were floating electrically, tied to ground, connected to a 9-volt battery, and subjected to a magnetic field. Standard deviations were notably higher for systems that were floating electrically.

TABLE 11

| Conductors | | | Non-Conductors | | |
|---|---|---|---|---|---|
| | Average | | | Average | |
| | Attenuation | Std Dev | | Attenuation | Std Dev |
| floating | −76.7 | 3.1 | Floating | −62.1 | 2.8 |
| grounded | −79.0 | 1.6 | | | |
| 9 V | −79.1 | 1.9 | open top | −61.6 | 1.30 |
| magnets | −77.7 | 2.4 | | | |

Table 12 compares the attenuation performance of the test assemblies fabricated from conductive materials at the four different electromagnetic conditions evaluated (electrically floating, tied to ground, charged to 9 volts, and subjected to a magnetic field). The table lists the actual signal attenuation achieved by each test assembly, the absolute reduction in signal strength measured for each test assembly, and the respective standard deviations. Absolute signal attenuation is simply the difference between the signal strength reduction associated with a test assembly and the signal strength reduction that occurred when the top of the wireless signal shielding chamber was left open. For example test assembly 8 yielded an average reduction of 73.6 dB, while the open chamber yielded an average reduction of 61.6 dB. The signal attenuation for assembly 8 therefore was 12.0 dB [73.6 dB−61.6 dB=12.0 dB]. Table 12 also lists the critical t-statistic (see equation 1) for each specific electromagnetic condition evaluated compared to the performance of the respective electrically floating assembly, also their differences in attenuation performance, and finally whether or not those performance differences were statistically significant.

TABLE 12

| | | | | | Test | Test | |
|---|---|---|---|---|---|---|---|
| | | | | | Assembly | Assembly | |
| | | | | | Critical | Absolute | Different |
| | | Signal | | | t-stat | difference | to Floating |
| | | Attenuation | Average | Std. | compared | to | Assembly |
| | | at 10 | Reduction | Dev | to | Floating | w/95% |
| | Assembly Number and Description | meters | (dB) | (dB) | Floating | (dB) | confidence |
| 1 | open top fully shielded | 0.0 | −61.6 | 1.30 | | | |
| 2 | closed top | 28.4 | −90.0 | 0.00 | | | |
| 8 | Foil backed (1 layer) Fiberglass | 12.0 | −73.6 | 5.73 | | | |
| 9 | Foil backed (1 layer) Fiberglass | 17.1 | −78.7 | 3.17 | 11.1 | 5.1 | No |
| | Grounded | | | | | | |
| 10 | Foil backed (1 layer) Fiberglass 9 V | 16.0 | −77.6 | 3.31 | 11.2 | 4.0 | No |
| | battery | | | | | | |
| 11 | Foil backed (1 layer) Fiberglass | 16.8 | −78.4 | 2.67 | 10.7 | 4.7 | No |
| | Magnets | | | | | | |
| 12 | Foil backed (3 layers) Fiberglass | 18.7 | −80.3 | 3.12 | | | |
| 13 | Foil backed (3 layers) Fiberglass | 19.4 | −81.0 | 1.25 | 5.7 | 0.7 | No |
| | Grounded | | | | | | |
| 14 | Foil backed (3 layers) Fiberglass 9 V | 17.7 | −79.3 | 1.32 | 5.7 | 1.0 | No |
| | battery | | | | | | |
| 15 | Foil backed (3 layers) Fiberglass | 15.8 | −77.4 | 2.86 | 7.2 | 2.9 | No |
| | Magnets | | | | | | |
| 16 | Wide Expanded Aluminum (1 layer) | 9.1 | −70.7 | 3.12 | | | |
| 17 | Wide Expanded Aluminum (1 layer) | 8.2 | −69.8 | 1.10 | 5.6 | 0.9 | No |
| | Grounded | | | | | | |
| 18 | Wide Expanded Aluminum (1 layer) | 12.5 | −74.1 | 0.94 | 5.5 | 3.5 | No |
| | 9 V Battery | | | | | | |
| 19 | Wide Expanded Aluminum (1 layer) | 11.2 | −72.8 | 3.93 | 8.5 | 2.1 | No |
| | Magnets | | | | | | |
| 20 | Wide Expanded Aluminum (2 layers) | 12.1 | −73.7 | 3.84 | | | |
| | Aligned | | | | | | |
| 21 | Wide Expanded Aluminum (2 layers) | 13.8 | −75.4 | 3.14 | 8.4 | 1.7 | No |
| | Aligned Grounded | | | | | | |
| 22 | Wide Expanded Aluminum (2 layers) | 10.9 | −72.5 | 3.13 | 8.4 | 1.2 | No |
| | Aligned 9 V Battery | | | | | | |
| 23 | Wide Expanded Aluminum (2 layers) | 9.4 | −71.0 | 0.93 | 6.7 | 2.7 | No |
| | Aligned Magnets | | | | | | |
| 24 | Wide Expanded Aluminum (2 layers) | 16.6 | −78.2 | 2.36 | | | |
| | Offset | | | | | | |
| 25 | Wide Expanded Aluminum (2 layers) | 18.3 | −79.9 | 2.03 | 5.3 | 1.7 | No |
| | Offset Grounded | | | | | | |
| 26 | Wide Expanded Aluminum (2 layers) | 15.6 | −77.2 | 2.18 | 5.4 | 0.9 | No |
| | Offset 9 V Battery | | | | | | |
| 27 | Wide Expanded Aluminum (2 layers) | 14.8 | −76.4 | 1.33 | 4.6 | 1.7 | No |
| | Offset Magnets | | | | | | |
| 28 | Narrow Expanded Aluminum | 9.8 | −71.4 | 1.38 | | | |
| | (1 layer) | | | | | | |
| 29 | Narrow Expanded Aluminum | 11.2 | −72.8 | 1.47 | 3.4 | 1.4 | No |
| | (1 layer) Grounded | | | | | | |
| 30 | Narrow Expanded Aluminum | 10.4 | −72.0 | 1.43 | 3.4 | 0.5 | No |
| | (1 layer) 9 V Battery | | | | | | |
| 31 | Narrow Expanded Aluminum | 8.4 | −70.0 | 3.75 | 6.8 | 1.4 | No |
| | (1 layer) Magnets | | | | | | |
| 32 | Narrow Expanded Aluminum | 13.3 | −74.9 | 4.61 | | | |
| | (2 layers) Aligned | | | | | | |
| 33 | Narrow Expanded Aluminum | 14.4 | −76.0 | 1.59 | 8.2 | 1.1 | No |
| | (2 layers) Aligned Grounded | | | | | | |
| 34 | Narrow Expanded Aluminum | 15.1 | −76.7 | 4.91 | 11.4 | 1.7 | No |
| | (2 layers) Aligned 9 V Battery | | | | | | |
| 35 | Narrow Expanded Aluminum | 10.7 | −72.3 | 2.37 | 8.8 | 2.6 | No |
| | (2 layers) Aligned Magnets | | | | | | |
| 36 | Narrow Expanded Aluminum | 14.9 | −76.5 | 2.00 | | | |
| | (2 layers) Offset | | | | | | |
| 37 | Narrow Expanded Aluminum | 18.0 | −79.6 | 0.56 | 3.5 | 3.1 | No |
| | (2 layers) Offset Grounded | | | | | | |
| 38 | Narrow Expanded Aluminum | 17.8 | −79.4 | 0.50 | 3.5 | 2.9 | No |
| | (2 layers) Offset 9 V Battery | | | | | | |
| 39 | Narrow Expanded Aluminum | 13.6 | −75.2 | 3.14 | 6.3 | 1.3 | No |
| | (2 layers) Offset Magnets | | | | | | |
| 40 | Perforated Steel (1 layer) | 19.1 | −80.7 | 3.89 | | | |
| 41 | Perforated Steel (1 layer) Grounded | 21.1 | −82.7 | 0.78 | 6.7 | 2.0 | No |
| 42 | Perforated Steel (1 layer) 9 V Battery | 21.9 | −83.5 | 0.73 | 6.7 | 2.8 | No |
| 43 | Perforated Steel (1 layer) Magnets | 23.4 | −85.0 | 1.30 | 6.9 | 4.2 | No |
| 44 | Perforated Steel (2 layers) Aligned | 20.9 | −82.5 | 1.53 | | | |
| 45 | Perforated Steel (2 layers) Aligned | 22.5 | −84.1 | 0.88 | 3.0 | 1.6 | No |
| | Grounded | | | | | | |
| 46 | Perforated Steel (2 layers) Aligned | 23.7 | −85.3 | 0.75 | 2.9 | 2.8 | No |
| | 9 V Battery | | | | | | |
| 47 | Perforated Steel (2 layers) Aligned | 21.4 | −83.0 | 1.74 | 3.9 | 0.5 | No |
| | Magnets | | | | | | |
| 48 | Perforated Steel (2 layers) Offset | 25.2 | −86.8 | 1.81 | | | |
| 49 | Perforated Steel (2 layers) Offset | 23.7 | −85.3 | 1.12 | 3.6 | 1.5 | No |
| | Grounded | | | | | | |
| 50 | Perforated Steel (2 layers) Offset 9 V | 23.4 | −85.0 | 1.03 | 3.5 | 1.8 | No |
| | Battery | | | | | | |
| 51 | Perforated Steel (2 layers) Offset | 20.7 | −82.3 | 0.92 | 3.4 | 4.5 | Yes |
| | Magnets | | | | | | |
| 52 | Fine Aluminum Mesh | 17.1 | −78.7 | 4.63 | | | |
| 53 | Fine Aluminum Mesh Grounded | 17.7 | −79.3 | 1.41 | 8.2 | 0.6 | No |
| 54 | Fine Aluminum Mesh 9 V Battery | 22.6 | −84.2 | 0.81 | 7.9 | 5.5 | No |
| 55 | Fine Aluminum Mesh Magnets | 18.2 | −79.8 | 4.48 | 10.9 | 1.2 | No |
| 56 | Aluminum Miniblinds (Open) | 4.1 | −65.7 | 4.48 | | | |
| 57 | Aluminum Miniblinds (Open) | 7.0 | −68.6 | 2.67 | 8.8 | 2.9 | No |
| | Grounded | | | | | | |
| 58 | Aluminum Miniblinds (Open) 9 V | 5.0 | −66.6 | 2.43 | 8.6 | 0.9 | No |
| | Battery | | | | | | |
| 59 | Aluminum Miniblinds (Open) | 5.1 | −66.7 | 1.66 | 8.1 | 1.0 | No |
| | Magnets | | | | | | |
| 60 | Aluminum Miniblinds (Closed) | 11.2 | −72.8 | 3.35 | | | |
| 61 | Aluminum Miniblinds (Closed) | 19.3 | −80.9 | 2.55 | 7.1 | 8.2 | No |
| | Grounded | | | | | | |
| 62 | Aluminum Miniblinds (Closed) 9 V | 17.8 | −79.4 | 2.04 | 6.6 | 6.6 | Yes |
| | Battery | | | | | | |
| 63 | Aluminum Miniblinds (Closed) | 18.9 | −80.5 | 4.45 | 9.4 | 7.7 | No |
| | Magnets | | | | | | |
| 64 | Low Density Fiberboard Foil | 18.1 | −79.7 | 2.47 | | | |
| | wrapped | | | | | | |
| 65 | Low Density Fiberboard Foil | 25.8 | −87.4 | 1.61 | 5.0 | 7.7 | Yes |
| | wrapped Grounded | | | | | | |
| 66 | Low Density Fiberboard Foil | 21.9 | −83.5 | 4.05 | 8.0 | 3.8 | No |
| | wrapped 9 V Battery | | | | | | |
| 67 | Low Density Fiberboard Foil | 25.3 | −86.9 | 1.49 | 4.9 | 7.2 | Yes |
| | wrapped magnets | | | | | | |
| 68 | Foil Covered (outer surfaces) | 18.7 | −80.3 | 1.58 | | | |
| | Fiberglass | | | | | | |
| 69 | Foil Covered (outer surfaces) | 20.3 | −81.9 | 0.69 | 2.9 | 1.6 | No |
| | Fiberglass Grounded | | | | | | |
| 70 | Foil Covered (outer surfaces) | 28.3 | −89.9 | 0.55 | 2.8 | 9.6 | Yes |
| | Fiberglass 9 V battery | | | | | | |
| 71 | Foil Covered (outer surfaces) | 23.3 | −84.9 | 1.94 | 4.2 | 4.5 | Yes |
| | Fiberglass Magnets | | | | | | |

Table 13 compares the attenuation performance of the non-conductive assemblies to the attenuation noted when the top of the wireless signal shielding chamber was left open. The table lists the actual signal attenuation achieved by each test assembly, the absolute reduction in signal strength measured for each test assembly, and the respective standard deviations. Table 13 also lists the critical t-statistic for each non-conductive assembly compared to the performance of the open chamber, also their differences in attenuation performance, and finally whether or not those performance differences were statistically significant.

TABLE 13

| | | | | | Critical t- | | |
|---|---|---|---|---|---|---|---|
| | | Attenuation | | | stat | Atenuation | |
| | | at 10 | Average | Std. | compared | difference | |
| Assembly Number & | | meters | Reduction | Dev | to Open | to Open | Different to Open |
| Description | | (dB) | (dB) | (dB) | (dB) | (dB) | w/ 95% confidence |
| 1 | open top fully shielded | 0.0 | −61.6 | 1.30 | | — | |
| 2 | closed top | 28.4 | −90.0 | 0.00 | 2.2 | 28.4 | Yes |
| 3 | 20 mm plywood | 5.5 | −67.1 | 2.18 | 4.3 | 5.5 | Yes |
| 4 | Fiberglass Insulation | −0.5 | −61.1 | 4.13 | 7.3 | 0.5 | No |
| 5 | Gypsum Board | 3.2 | −64.8 | 3.16 | 5.8 | 3.2 | No |
| 6 | Low Density Fiberboard | −2.8 | −58.8 | 3.30 | 6.0 | 2.8 | No |
| 7 | Vinyl Miniblinds (Closed) | −2.8 | −58.8 | 1.19 | 3.0 | 2.8 | No |

Table 14 compares the attenuation performance of the various thin aluminum (foil and mesh) based assemblies when they were tied to ground. The table lists the actual signal attenuation achieved by each test assembly and their respective standard deviations. It also lists the critical t-statistic for each assembly compared to the performance of fiberglass board backed by a single layer of aluminum foil, as well as their differences in attenuation performance, and whether or not those performance differences were statistically significant. Table 14 also lists the critical t-statistic for each assembly compared to the performance of low density fiberboard wrapped with aluminum foil, as well as their differences in attenuation performance, and finally whether or not those performance differences were statistically significant.

TABLE 14

| | | | | | | t-test | | |
|---|---|---|---|---|---|---|---|---|
| | | | t-test | | | value | | |
| | | | value | | | different | | Different |
| | | | different | | Different | w/ 95% | Difference | to |
| Grounded | | | w/ 95% | Difference | w/ 95% | confidence | to | wrapped |
| Assembly | Attenuation | Standard | confidence | to 1 layer | confidence | to | wrapped | w/ 95% |
| Description | (dB) | Deviation | to 1 layer | (dB) | to 1 layer | wrapped | (dB) | confidence |
| Foil | 17.1 | 3.17 | | | | 6 | 8.7 | Yes |
| backed | | | | | | | | |
| (1 layer) | | | | | | | | |
| Fiberglass | | | | | | | | |
| Foil | 19.4 | 1.25 | 5.8 | 2.3 | No | 3.4 | 6.4 | Yes |
| backed | | | | | | | | |
| (3 layers) | | | | | | | | |
| Fiberglass | | | | | | | | |
| Low | 25.8 | 1.61 | 6.0 | 8.7 | Yes | | | |
| Density | | | | | | | | |
| Fiberboard | | | | | | | | |
| Foil | | | | | | | | |
| wrapped | | | | | | | | |
| Fine | 17.7 | 1.41 | 5.9 | 0.6 | No | 3.6 | 8.1 | Yes |
| Aluminum | | | | | | | | |
| Mesh | | | | | | | | |
| Foil | 20.3 | 0.69 | 5.5 | 3.2 | No | 3.0 | 5.5 | Yes |
| Covered | | | | | | | | |
| (outer | | | | | | | | |
| surfaces) | | | | | | | | |
| Fiberglass | | | | | | | | |

Table 15 compares the attenuation performance of the various thin aluminum (foil and mesh) based assemblies when they were charged to 9 volts. The table lists the actual signal attenuation achieved by each test assembly and their respective standard deviations. It also lists the critical t-statistic for each assembly compared to the performance of fiberglass board backed by a single layer of aluminum foil, as well as their differences in attenuation performance, and whether or not those performance differences were statistically significant. Table 15 also lists the critical t-statistic for each assembly compared to the performance of the fiberglass board faced top and bottom with a layer of aluminum foil, as well as their differences in attenuation performance, and finally whether or not those performance differences were statistically significant.

TABLE 15

| | | | | | | t-test | | |
|---|---|---|---|---|---|---|---|---|
| | | | t-test | | | value | | |
| | | | value | | | different | | Different |
| | | | different | | Different | w/ 95% | Difference | to foil |
| 9 Volt | | | w/ 95% | Difference | w/ 95% | confidence | to foil | covered |
| Assembly | Attenuation | Standard | confidence | to 1 layer | confidence | to foil | covered | w/ 95% |
| Description | (dB) | Deviation | to 1 layer | (dB) | to 1 layer | covered | (dB) | confidence |
| Foil | 16.0 | 3.17 | | | | 5.5 | 12.3 | Yes |
| backed | | | | | | | | |
| (1 layer) | | | | | | | | |
| Fiberglass | | | | | | | | |
| Foil | 17.7 | 1.25 | 5.8 | 1.7 | No | 2.4 | 10.6 | Yes |
| backed | | | | | | | | |
| (3 layers) | | | | | | | | |
| Fiberglass | | | | | | | | |
| Low | 21.9 | 1.61 | 6.0 | 5.9 | No | 3.0 | 6.4 | Yes |
| Density | | | | | | | | |
| Fiberboard | | | | | | | | |
| Foil | | | | | | | | |
| wrapped | | | | | | | | |
| Fine | 22.6 | 1.41 | 5.9 | 6.6 | Yes | 2.7 | 5.7 | Yes |
| Aluminum | | | | | | | | |
| Mesh | | | | | | | | |
| Foil | 28.3 | 0.69 | 5.5 | 12.3 | Yes | | | |
| Covered | | | | | | | | |
| (outer | | | | | | | | |
| surfaces) | | | | | | | | |
| Fiberglass | | | | | | | | |

Table 16 compares the attenuation performance of the wide expanded aluminum assemblies when they were tied to ground. The table lists the actual signal attenuation achieved by each test assembly and their respective standard deviations. It also lists the critical t-statistic for each assembly compared to the performance of a single layer of wide expanded aluminum, as well as their differences in attenuation performance, and whether or not those performance differences were statistically significant. Table 16 also lists the critical t-statistic comparing the performance of the two layer aligned assembly with the performance of the two layer offset assembly, as well as their differences in attenuation performance, and finally whether or not those performance differences were statistically significant.

TABLE 16

| | | | | | | t-test | | |
|---|---|---|---|---|---|---|---|---|
| | | | t-test | | | value | | Different |
| | | | value | | | different | | to 2 |
| | | | different | | Different | w/ 95% | Difference | layer |
| Grounded | | | w/ 95% | Difference | w/ 95% | confidence | to 2 Layer | aligned w/ |
| Assembly | Attenuation | Standard | confidence | to 1 layer | confidence | to 2 layer | Aligned | 95% |
| Description | (dB) | Deviation | to 1 layer | (dB) | to 1 layer | aligned | (dB) | confidence |
| Wide | 8.2 | 1.10 | | | | | | |
| Expanded | | | | | | | | |
| Aluminum | | | | | | | | |
| (1 layer) | | | | | | | | |
| Wide | 13.8 | 3.14 | 5.6 | 5.6 | Yes | | | |
| Expanded | | | | | | | | |
| Aluminum | | | | | | | | |
| (2 layers) | | | | | | | | |
| Aligned | | | | | | | | |
| Wide | 18.3 | 2.03 | 3.9 | 10.1 | Yes | 6.3 | 4.5 | No |
| Expanded | | | | | | | | |
| Aluminum | | | | | | | | |
| (2 layers) | | | | | | | | |
| Offset | | | | | | | | |

Table 17 compares the attenuation performance of the narrow expanded aluminum assemblies when they were tied to ground. The table lists the actual signal attenuation achieved by each test assembly and their respective standard deviations. It also lists the critical t-statistic for each assembly compared to the performance of a single layer of narrow expanded aluminum, as well as their differences in attenuation performance, and whether or not those performance differences were statistically significant. Table 17 also lists the critical t-statistic comparing the performance of the two layer aligned assembly with the performance of the two layer offset assembly, as well as their differences in attenuation performance, and finally whether or not those performance differences were statistically significant.

TABLE 17

| | | | | | | t-test | | |
|---|---|---|---|---|---|---|---|---|
| | | | t-test | | | value | | |
| | | | value | | | different | | Different |
| | | | different | | Different | w/ 95% | Difference | to 2 layer |
| Grounded | | | w/ 95% | Difference | w/ 95% | confidence | to 2 Layer | aligned w/ |
| Assembly | Attenuation | Standard | confidence | to 1 layer | confidence | to 2 layer | Aligned | 95% |
| Description | (dB) | Deviation | to 1 layer | (dB) | to 1 layer | aligned | (dB) | confidence |
| Narrow | 11.2 | 1.47 | | | | | | |
| Expanded | | | | | | | | |
| Aluminum | | | | | | | | |
| (1 layer) | | | | | | | | |
| Narrow | 14.4 | 1.59 | 3.7 | 3.2 | No | | | |
| Expanded | | | | | | | | |
| Aluminum | | | | | | | | |
| (2 layers) | | | | | | | | |
| Aligned | | | | | | | | |
| Narrow | 15.1 | 0.56 | 2.7 | 3.9 | Yes | 2.8 | 0.7 | No |
| Expanded | | | | | | | | |
| Aluminum | | | | | | | | |
| (2 layers) | | | | | | | | |
| Offset | | | | | | | | |

Table 18 compares the attenuation performance of the perforated steel assemblies when they were tied to ground. The table lists the actual signal attenuation achieved by each test assembly and their respective standard deviations. It also lists the critical t-statistic for each assembly compared to the performance of a single layer of perforated steel, as well as their differences in attenuation performance, and whether or not those performance differences were statistically significant. Table 18 also lists the critical t-statistic comparing the performance of the two layer aligned assembly with the performance of the two layer offset assembly, as well as their differences in attenuation performance, and finally whether or not those performance differences were statistically significant.

TABLE 18

| | | | t-test | | | critical t- | | |
|---|---|---|---|---|---|---|---|---|
| | | | value | | | test value | | Different |
| | | | different | | Different | to 2 Layer | Difference | to 2 Layer |
| Grounded | | | w/ 95% | Difference | w/ 95% | Aligned | to 2 Layer | Aligned |
| Assembly | Attenuation | Standard | confidence | to 1 layer | confidence | 95% | Aligned | w/ 95% |
| Description | (dB) | Deviation | to 1 layer | (dB) | to 1 layer | confidence | (dB) | confidence |
| Perforated | 21.1 | 0.78 | | | | | | |
| Steel | | | | | | | | |
| (1 layer) | | | | | | | | |
| Perforated | 22.5 | 0.88 | 2.0 | 1.4 | No | | | |
| Steel | | | | | | | | |
| (2 layers) | | | | | | | | |
| Aligned | | | | | | | | |
| Perforated | 23.7 | 1.12 | 2.3 | 2.6 | Yes | 2.4 | 1.2 | No |
| Steel | | | | | | | | |
| (2 layers) | | | | | | | | |
| Offset | | | | | | | | |

Table 19 compares the attenuation performance of the grounded open and closed aluminum mini-blinds to the closed vinyl mini-blinds. The table lists the actual signal attenuation achieved by each test assembly and their respective standard deviations. It also lists the critical t-statistic for each assembly compared to the performance of the open aluminum mini-blinds, as well as their differences in attenuation performance, and whether or not those performance differences were statistically significant.

TABLE 19

| | | | t-test | | |
|---|---|---|---|---|---|
| | | | value | | |
| | | | different | | Different |
| | | | w/ 95% | Difference | w/ 95% |
| | | | confidence | to open | confidence |
| | Attenuation | Standard | to open | blinds | to open |
| Grounded Assembly Description | (dB) | Deviation | blinds | (dB) | blinds |
| Vinyl Miniblinds (Closed) | −2.8 | 1.19 | 4.9 | 9.8 | Yes |
| Aluminum Miniblinds (Open) | 7.0 | 2.67 | | | |
| Aluminum Miniblinds (Closed) | 19.3 | 2.55 | 6.2 | 12.3 | Yes |

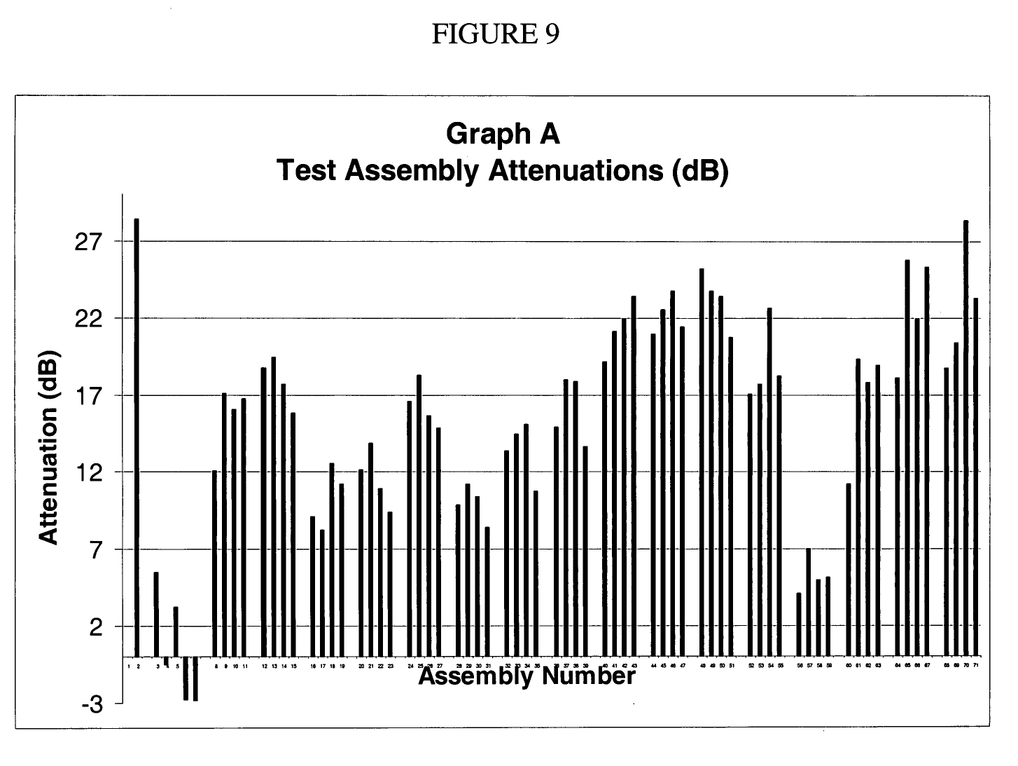

Graph A which is shown in FIG. 9 is a plot showing the attenuation performance of seventy-one test assembly conditions evaluated during testing. The graph shows that even though a wide range of attenuation performance was achieved, very few test assemblies approached the performance of the closed chamber, i.e. assembly 2. The test assembly descriptions associated with the individual assembly numbers can be found in Table 10.

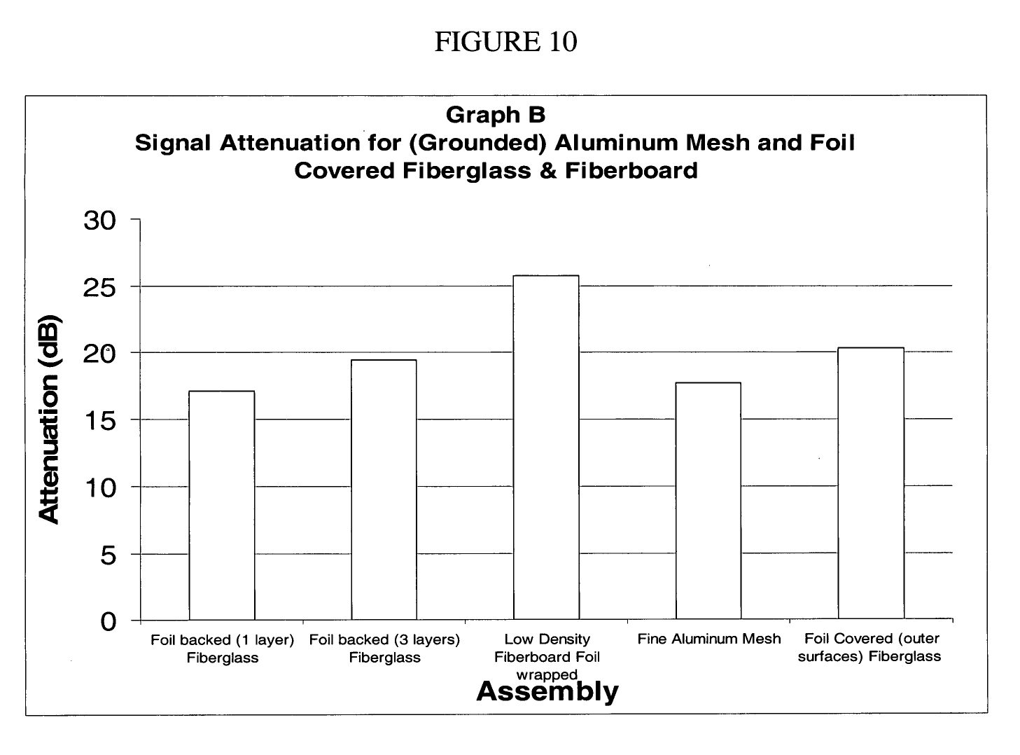

Graph B which is shown in FIG. 10 is a plot showing the attenuation performance associated with various thin aluminum (foil and mesh) based assemblies in which the assemblies were tied to ground. The graph shows the foil wrapped low density fiberboard performed significantly better than any of the other thin aluminum assemblies tied to ground.

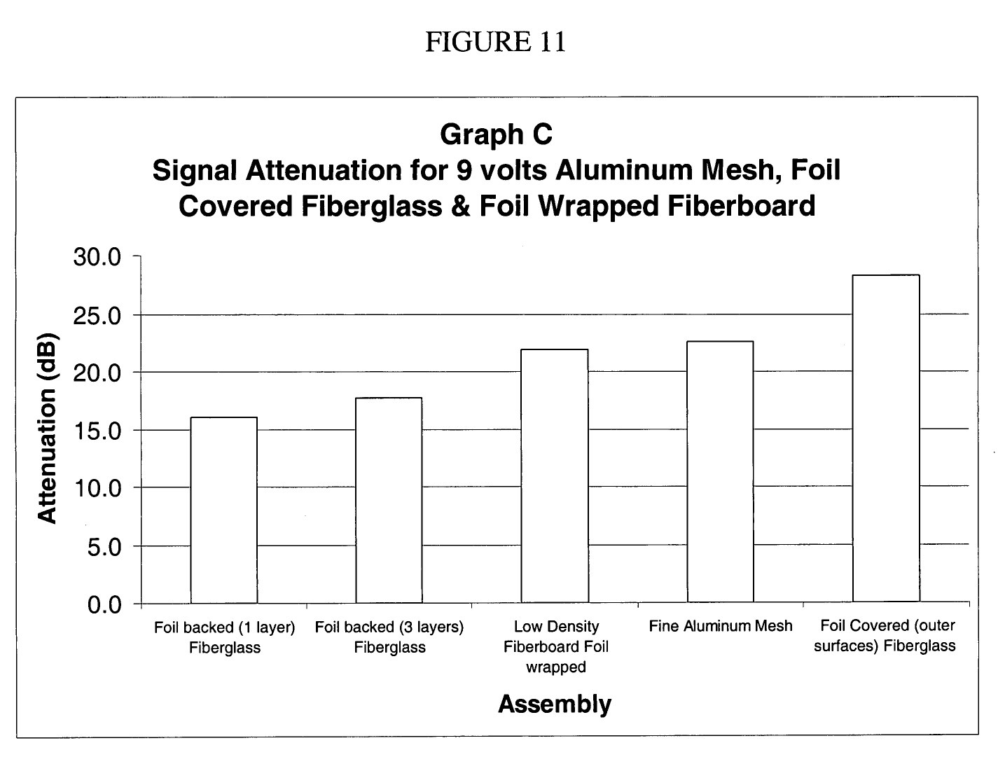

Graph C which is shown in FIG. 11 is a plot showing the attenuation performance associated with various thin aluminum (foil and mesh) based assemblies in which the assemblies were charged at 9 volts. The graph shows the fiberglass board faced top and bottom with a layer of aluminum foil performed significantly better than any of the other thin aluminum assemblies charged at 9 volts.

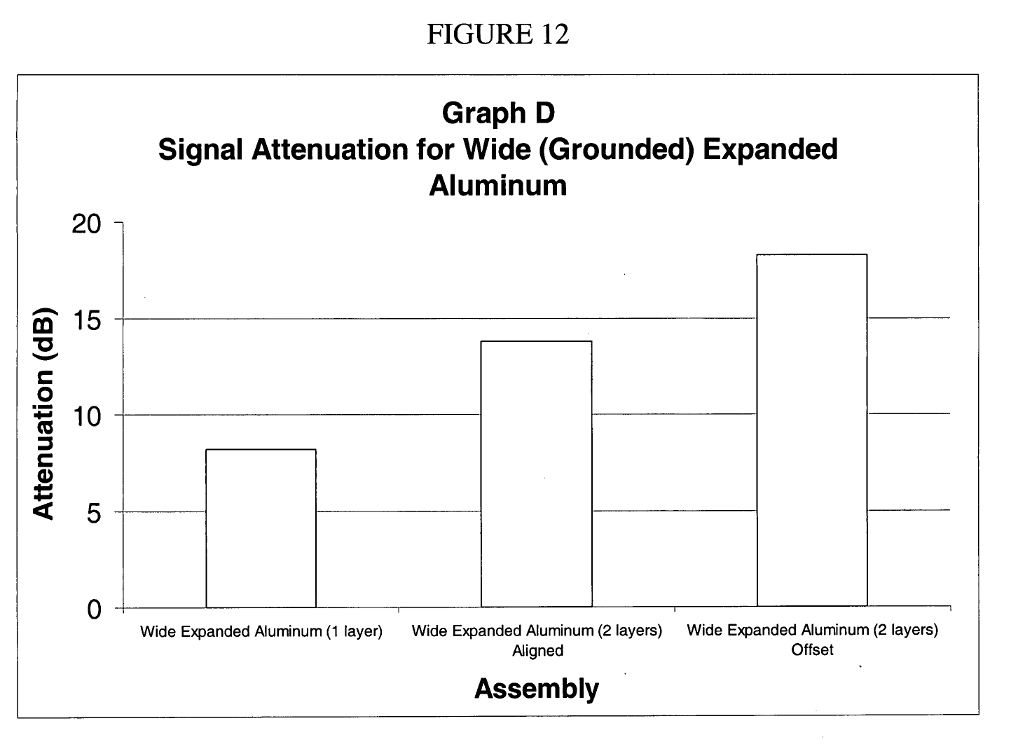

Graph D which is shown in FIG. 12 is a plot showing the attenuation performance of wide expanded aluminum assemblies which were tied to ground. The graph shows the assembly performance was notably enhanced by adding an aligned second layer, and enhanced yet again by offsetting the two layers.

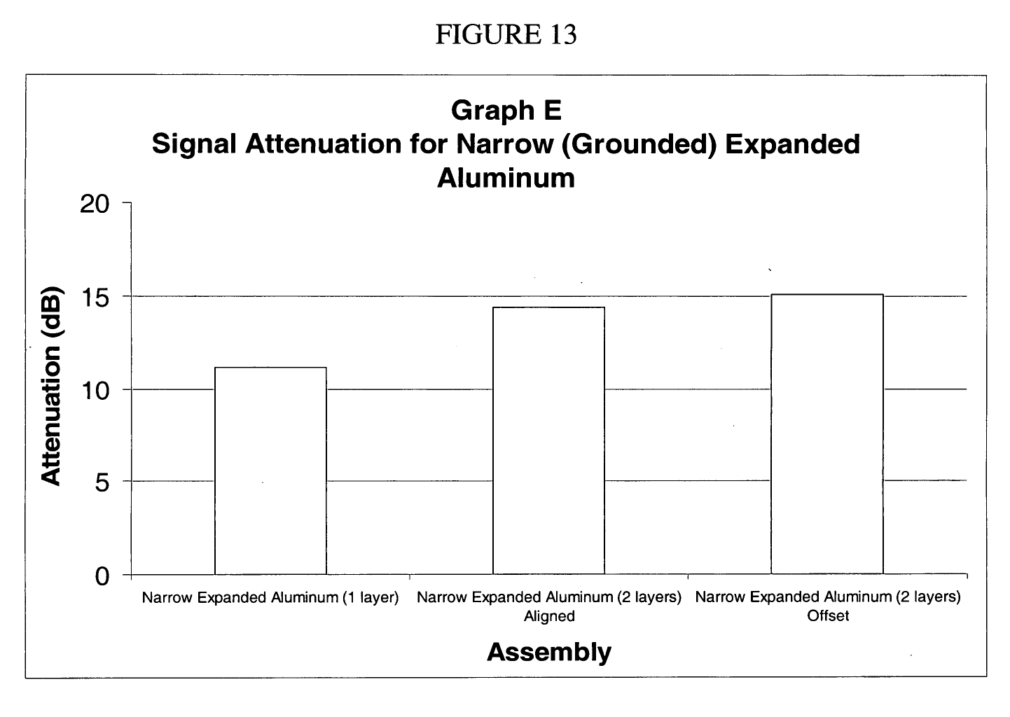

Graph E which is shown in FIG. 13 is a plot showing the attenuation performance of narrow expanded aluminum assemblies which were tied to ground. In contrast to wide expanded aluminum assemblies, the graph shows that assembly performance was only slightly enhanced by adding a second layer, and not significantly enhanced by offsetting the two layers.

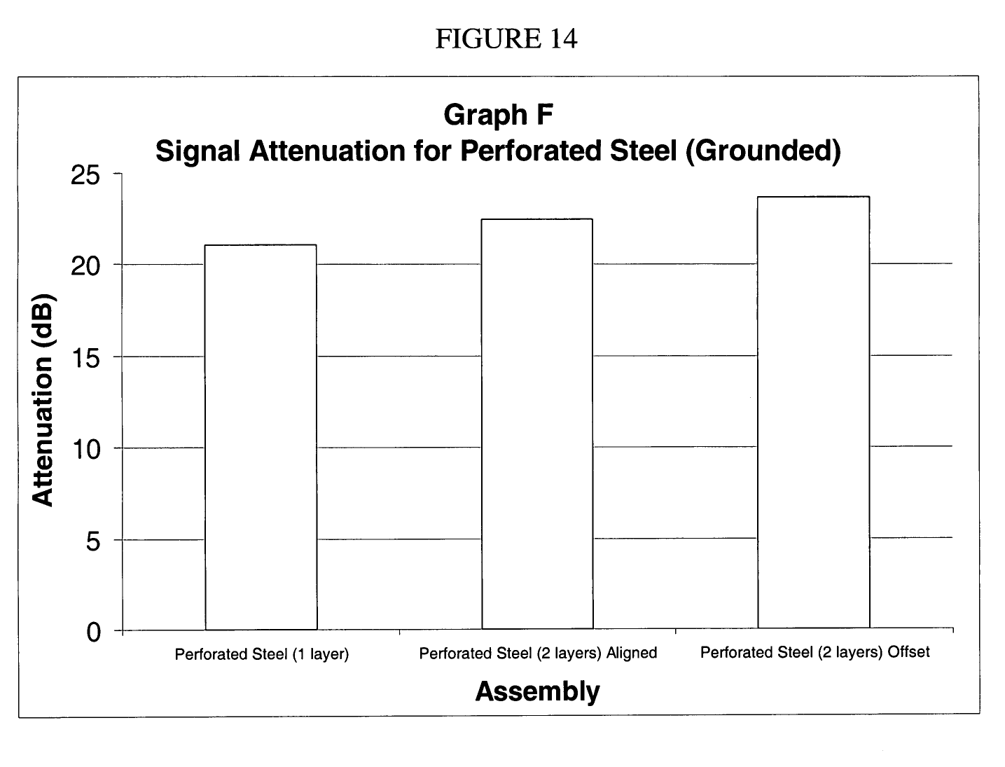

Graph F which is shown in FIG. 14 is a plot showing the attenuation performance of perforated steel assemblies which were tied to ground. The graph shows that assembly performance was only slightly enhanced by adding a second layer, and not significantly enhanced by offsetting the two layers.

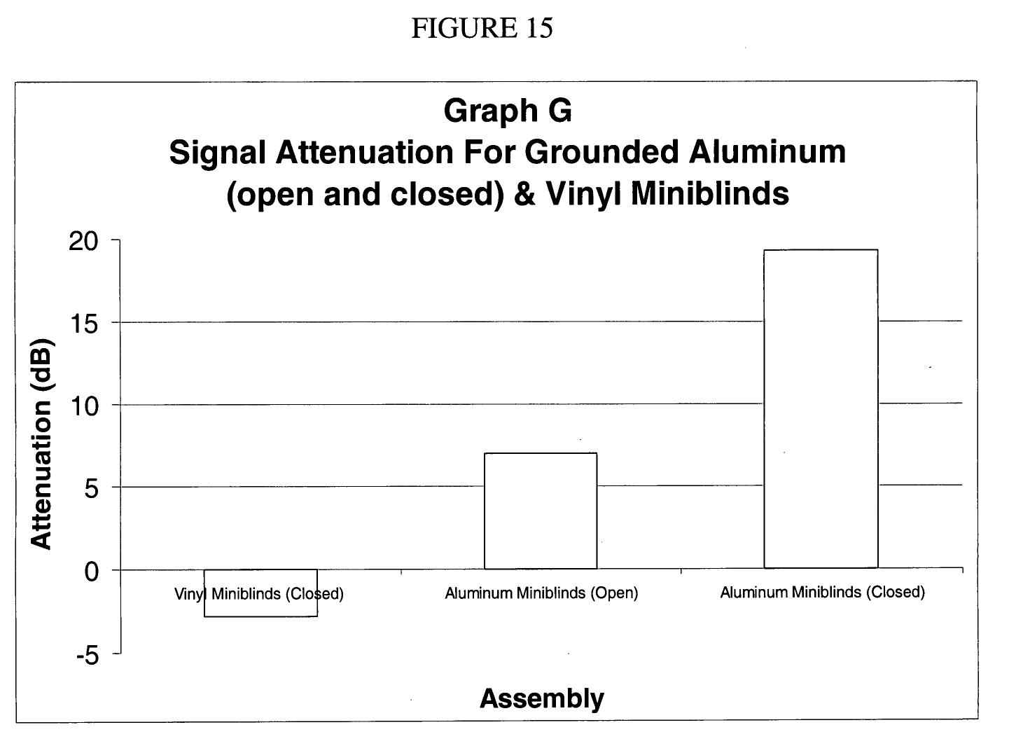

Graph G which is shown in FIG. 15 is a plot showing the attenuation performance of grounded open aluminum mini-blinds, closed aluminum mini-blinds and closed vinyl mini-blinds. The graph shows that the aluminum blinds in any orientation yield significantly more attenuation than vinyl blinds. Furthermore, closed aluminum mini-blinds perform significantly better than the open aluminum mini-blinds.

In order to determine if the differences in WLAN signal attenuation recorded for the different test assemblies were statistically significant, a t-statistic test with a 95% confidence value was used. More specifically, by knowing the means and the standard deviations of the two data sets as well as the degrees of freedom present, a t-statistic test can be used to determine a level of confidence that a meaningful difference in the means exists. For this study there were thirty trials for each assembly (n=30) and, in turn, there were 29 (n−1) degrees of freedom.

t-critical≧(mean₁−mean₂)/√(σ₁²+σ₂²) Equation 1

The t-critical value for 95% confidence and 29 degrees of freedom is 1.699. If the value on the right side of equation 1 is greater than 1.699, then one can state with at least 95% confidence that the two sample populations are different.

The two largest values for standard deviation obtained in the course of this experiment were: 5.73 dB and 4.63 dB. The largest potential value for the denominator in Equation 1 is therefore 7.4 dB [√(7.43²+4.63²)=7.4 dB]. Multiplying the denominator by the critical t-value for 95% confidence (1.699) yields a value of 12.4 dB. So if the difference between the mean signal attenuation of two different test assemblies is greater than 12.4 dB, it can be stated with at least 95% confidence that their attenuation performance is truly different. Using the values for the smallest standard deviations, the denominator for the right side of Equation 1 would be 0.7 dB [4(0.50²+0.55²)=0.7 dB]. Multiplying that value by 1.699 yields 1.3 dB. This indicates that if the difference between two mean attenuations is less than 1.3 dB, one cannot be 95% confident that the difference is not simply due to random error. For situations where the difference in signal attenuation is between 1.3 and 12.4 dB, the specific t-statistic for those test conditions will need to be calculated.

From the data, it can be stated with at least 95% confidence that all the assemblies incorporating metal provided a statistically significant level of attenuation. The relative performance of all assemblies tested is shown in FIG. 9. It can also be stated with at least 95% confidence that adding a second layer of expanded or perforated metal can significantly increase the attenuation for either type of assembly. Offsetting the expanded or perforated metal layers did increase attenuation; however, in all case the increases were not statistically significant. FIG. 13 shows that for the narrow expanded aluminum test assemblies the attenuation increase that occurred when the layers were offset was meager, less than 1 dB. FIG. 12 shows that for the wide expanded aluminum the increase was noticeable (4.5 dB), but unfortunately the standard deviations were also quite large (2-3 dB). In the case of the perforated metal, the perforations evaluated were approximately three times the diameter of the holes in the perforated metal used to make microwave oven doors. For safety reasons, microwave oven doors are expected to provide complete attenuation. Although it was hoped that offsetting the perforated metal layers would improve the attenuation from good to excellent that simply did not occur. This is clearly displayed in FIG. 14.

These two highest attenuations provided by a test assembly were 28.3 dB by the foil covered fiberglass board at 9 volts, and 25.8 dB provided by the foil wrapped low density fiberboard at ground. The increases in attenuation from these two test assembly conditions (when compared to their performance while floating electrically) were also quite large at 9.6 and 7.7 dB respectively. The highest attenuation increase due to a mechanical change occurred when the aluminum mini-blinds were closed, improving attenuation by 12.2 dB. This increase is shown in Graph G. These results clearly indicate that a system capable of selectively shielding WLAN signals on demand can indeed be constructed by using standard building materials. Aluminum foil backed fiberglass insulation is a common building material. One could simply insert two layers of foil backed fiberglass into the outer walls of the structure, so that the foil layers are separated from each other, and connect the two foil layers via an electrical circuit. When the circuit was open one level of attenuation would be obtained, and when the circuit was closed (either grounded or charged) a greater level of attenuation would occur. One could also achieve the same effect by taking standard materials such as fiberglass board, drywall or ceiling tiles, attaching metal foil to both sides, and then connecting the two sides of the material via an electrical circuit. Building with materials of this sort would allow one to better control wireless signal propagation.

Metal of all type was found to provide some degree of attenuation. Therefore a foil backed wallpaper, or even a paint filled with metal particles would also be expected to provide some attenuation. Adding this type of material to the walls of a building may prove to be the simplest and most cost effective way for a building or home owner to increase signal attenuation and thus data network security. If a conductive layer of this type were tied electrically to a separate conductive layer, then enhanced signal attenuation could be achieved on demand. Another approach to ensuring data network security would be by using steel or aluminum siding on the building instead of vinyl, wood or bricks for the exterior cladding. In addition using aluminum blinds, instead of vinyl, cloth or wooden blinds to cover windows and glass doors would allow the occupants to open and close their signal shields on demand.

In conclusion, the results from testing show that a WLAN can be selectively shielded, providing greater data network security while maintaining the freedom associated with the use of wireless networks. In particular, the assemblies tested which utilized a metal sheet/mesh, and which were tied to ground, attenuated the WLAN signals. As shown by the data, changing the size of the open area, affects the level of signal attenuation.

Substrates with one to three layers of aluminum foil provided moderate attenuation. However, two layers of aluminum foil spaced at a distance of several centimeters from each other, and tied together electrically, provided almost complete signal attenuation.

Additionally, while open aluminum mini-blinds provided just slight attenuation, closed aluminum mini-blinds provided substantial attenuation. In contrast, non-metallic construction materials such as plywood, gypsum board, fiberglass insulation, and vinyl provided virtually no WLAN signal attenuation. Even the dense concrete used to construct the wireless signal isolation chamber provided little to no attenuation. It was not until the chamber was both lined with sheet metal and wrapped with multiple layers of metal foil that it was able to fully attenuate the WLAN signals.

It will be understood by those of skill in the art that variations on the embodiments set forth herein are possible and within the scope of the present invention. The embodiments set forth above and many other additions, deletions, and modifications may be made by those of skill in the art without departing from the spirit and scope of the invention. For example, construction materials, such as gypsum board or ceiling tiles with embedded perforated metal cores, can also be used. For existing buildings it may be possible to create wall papers, or floor coverings that have conductors, such as metal foil, embedded within them, or to simply install metal blinds that when drawn isolate the space from WLAN signals.

I claim:

1. A shield for attenuating wireless signals comprising:
at least one electrically conductive member which is capable of being selectively coupled to a ground member.

2. The shield of claim 1, wherein the wireless signals are wireless local area network signals.

3. The shield of claim 1, wherein the at least one electrically conductive member has openings extending therethrough.

4. The shield of claim 3, wherein first and second conductive members are provided proximate each other and are selectively coupled to one another to allow a signal to pass through the first and second conductive members.

5. The shield of claim 4, wherein first and second conductive members overlay one another.

6. The shield of claim 3, wherein first and second conductive members are provided proximate each other and are selectively coupled to one another to block a signal from passing through the conductive members.

7. The shield of claim 6, wherein first and second conductive members overlay one another.

8. The shield of claim 1, wherein the at least one electrically conductive member includes metal material.

9. The shield of claim 1, wherein the at least one electrically conductive member is a metal film.

10. The shield of claim 1, wherein the at least one electrically conductive member is a plastic film which includes metal material.

11. The shield of claim 1, wherein the at least one electrically conductive member is embedded in a ceiling tile.

12. A shield for attenuating wireless signals comprising:
first and second continuous conductive members which are selectively connected to one another electrically.

13. The shield of claim 12, wherein the first and second continuous conductive members are provided proximate each other and are selectively coupled to one another to allow a signal to pass through the first and second conductive members.

14. The shield of claim 13, wherein the first and second continuous conductive members overlay one another.

15. The shield of claim 12, wherein the first and second continuous conductive members are provided proximate each other and are selectively coupled to one another to block a signal from passing through the conductive members.

16. The shield of claim 15, wherein the first and second continuous conductive members overlay one another.

17. The shield of claim 12, wherein each of the first and second continuous conductive members includes metal material.

18. The shield of claim 12, wherein at least one of the first and second continuous conductive members is embedded in a ceiling tile.

19. A shield for attenuating wireless signals comprising:
at least one electrically conductive member which is capable of being selectively coupled to an electron flow.

20. The shield of claim 19, wherein the at least one electrically conductive member is embedded in a ceiling tile.
